(19) United States
(12) Patent Application Publication
(10) Pub. No.: US 2024/0235485 A1
(43) Pub. Date: Jul. 11, 2024

(54) TRACKER MODULE AND COMMUNICATION DEVICE

(71) Applicant: Murata Manufacturing Co., Ltd., Nagaokakyo-shi (JP)

(72) Inventors: Takeshi KOGURE, Nagaokakyo-shi (JP); Tomohide ARAMATA, Nagaokakyo-shi (JP); Yuuki FUKUDA, Nagaokakyo-shi (JP); Toshiki MATSUI, Nagaokakyo-shi (JP)

(21) Appl. No.: 18/616,654

(22) Filed: Mar. 26, 2024

Related U.S. Application Data
(63) Continuation of application No. PCT/JP2022/035971, filed on Sep. 27, 2022.

(30) Foreign Application Priority Data
Sep. 29, 2021 (JP) 2021-159654

(51) Int. Cl. H03F 1/02; H03F 3/24

(52) U.S. Cl. CPC H03F 1/0233; H03F 3/245; H03F 2200/105; H03F 2200/451

(57) ABSTRACT

A tracker module includes a module laminate, a first integrated circuit and a second integrated circuit on the module laminate, and a capacitor disposed on the module laminate and included in a switched-capacitor circuit. The switched-capacitor circuit is configured to generate discrete voltages based on an input voltage. The first integrated circuit includes a switch included in the switched-capacitor circuit. The second integrated circuit includes a switch included in at least one of a supply modulator and a pre-regulator circuit. The supply modulator is configured to selectively output at least one of the discrete voltages based on an envelope signal. The pre-regulator circuit is configured to convert the input voltage into a first voltage and output the first voltage to the switched-capacitor circuit. A distance between the first integrated circuit and the capacitor is shorter than a distance between the second integrated circuit and the capacitor.

### CROSS REFERENCE TO RELATED APPLICATIONS

This application is a continuation of International Application No. PCT/JP2022/035971, filed Sep. 27, 2022, which claims priority to Japanese Patent Application No. 2021-159654, filed Sep. 29, 2021, the entire contents of each of which are hereby incorporated by reference in their entirety.

### TECHNICAL FIELD

The present disclosure relates to a tracker module and a communication device.

### BACKGROUND

In a related disclosure, such as U.S. Pat. No. 9,755,672 (hereinafter “Patent Document 1”), a power supply modulator circuit (e.g., an envelope tracking system) is provided. As described therein, the power supply modulator circuit supplies a power supply voltage to a power amplifier circuit based on an envelope signal. The power supply modulator circuit includes a magnetic converter circuit (or a magnetic regulation stage: pre-regulator circuit) that converts a voltage, a switched-capacitor circuit (or a switched-capacitor voltage balancer stage) that generates a plurality of voltages having different voltage levels from the voltage, and a supply modulator (or an output switching stage) that selects and outputs at least one of the plurality of voltages. The magnetic converter circuit includes a switch and a power inductor. The capacitor circuit includes a switch and a capacitor. The supply modulator includes a switch.

However, in the power supply modulator circuit according to the related Patent Document 1, when a tracker module is configured by mounting a switch of the switched-capacitor circuit and a switch of the supply modulator or the pre-regulator circuit on a module laminate as different switch integrated circuits, a wire connecting the switch and a capacitor of the switched-capacitor circuit is long. The wire is required to have a low resistance because a large current generated by high-speed charging and discharging of the capacitor flows through the wire. However, when the wire is long, a resistance loss in the wire is increased, and output characteristics of the power supply voltage of the tracker module may deteriorate.

### SUMMARY OF THE INVENTION

In view of the foregoing the present disclosure provides a tracker module and a communication device in which deterioration of output characteristics of a power supply voltage is suppressed.

According to an aspect of the disclosure, a tracker module (or tracker module structure) is provided. The tracker module includes a module laminate, a first integrated circuit and a second integrated circuit that are disposed on the module laminate, and a capacitor that is disposed on the module laminate and that is included in a switched-capacitor circuit. The switched-capacitor circuit is configured to generate a plurality of discrete voltages based on an input voltage. The first integrated circuit includes a switch of the switched-capacitor circuit. The second integrated circuit includes a switch that is included in a supply modulator. The supply modulator is configured to selectively output at least one of the plurality of discrete voltages based on an envelope signal. A distance between the first integrated circuit and the capacitor is shorter than a distance between the second integrated circuit and the capacitor.

According to another aspect of the disclosure, a tracker module is provided. The tracker module includes a module laminate, a first integrated circuit and a second integrated circuit that are disposed on the module laminate, and a capacitor that is disposed on the module laminate and included in a switched-capacitor circuit. The switched-capacitor is configured to generate a plurality of discrete voltages based on an input voltage. The first integrated circuit includes a switch of the switched-capacitor circuit, and the second integrated circuit includes a switch of a pre-regulator circuit. The pre-regulator is configured to convert the input voltage into a first voltage and output the first voltage to the switched-capacitor circuit. A distance between the first integrated circuit and the capacitor is shorter than a distance between the second integrated circuit and the capacitor.

According to yet another aspect of the disclosure, a tracker module is provided. The tracker module includes a module laminate, and a first circuit and a second circuit. The first circuit includes a first capacitor and a second electrode. The first capacitor includes a first electrode and a second electrode, and the second capacitor includes a third electrode and a fourth electrode. According to an exemplary aspect, the tracker module also includes a first switch, a second switch, a third switch, a fourth switch, a fifth switch, a sixth switch, a seventh switch, and an eighth switch. One end of the first switch and one end of the third switch are connected to the first electrode. One end of the second switch and one end of the fourth switch are connected to the second electrode. One end of the fifth switch and one end of the seventh switch are connected to the third electrode. One end of the sixth switch and one end of the eighth switch are connected to the fourth electrode. Another end of the first switch, another end of the second switch, another end of the fifth switch, and another end of the sixth switch are connected to each other. Another end of the third switch is connected (or coupled) to another end of the seventh switch, and another end of the fourth switch is connected to another end of the eighth switch. The second circuit includes a first output terminal, a ninth switch, and a tenth switch. The ninth switch is connected between (i) the first output terminal and (ii) the other end of the first switch, the other end of the second switch, the other end of the fifth switch, and the other end of the sixth switch, and the tenth switch connected (or coupled) between (i) the first output terminal and (ii) the other end of the third switch and the other end of the seventh switch. The first switch to the eighth switch are included in a first integrated circuit. The ninth switch and the tenth switch are included in a second integrated circuit. The first capacitor, the second capacitor, the first integrated circuit, and the second integrated circuit are disposed on the module laminate. A distance between the first integrated circuit and the first capacitor is shorter than a distance between the second integrated circuit and the first capacitor.

The tracker module can include a third capacitor and a fourth capacitor. The third capacitor includes a fifth electrode and a sixth electrode. The fifth electrode is coupled to the other end of the first switch, the other end of the second switch, the other end of the fifth switch, and the other end of the sixth switch. In an example, the sixth electrode of the third capacitor is coupled to the other end of the third switch and the other end of the seventh switch. In an example, the sixth electrode of the third capacitor is coupled to the other end of the fourth switch and the other end of the eighth switch. The fourth capacitor includes a seventh electrode and an eighth electrode. The seventh electrode is coupled to the other end of the first switch, the other end of the second switch, the other end of the fifth switch, and the other end of the sixth switch. The eighth electrode is coupled to the other end of the fourth switch and the other end of the eighth switch.

According to the present disclosure, a tracker module and a communication device in which deterioration of output characteristics of a power supply voltage is suppressed can be provided.

### BRIEF DESCRIPTION OF DRAWINGS

FIG. 1 is a circuit block diagram of a power supply circuit and a communication device according to an exemplary embodiment.

FIG. 2A is a graph illustrating an example of transition of a power supply voltage in a digital ET mode.

FIG. 2B is a graph illustrating an example of transition of the power supply voltage in an analog ET mode.

FIG. 3 is a diagram illustrating a circuit configuration example of the power supply circuit according to the exemplary embodiment.

FIG. 4 is a plan view of a tracker module according to Example 1.

FIG. 5 is a first cross-sectional view of the tracker module according to Example 1.

FIG. 6 is a second cross-sectional view of the tracker module according to Example 1.

FIG. 7 is a plan view of a tracker module according to Example 2.

FIG. 8 is a plan view of a tracker module according to Example 3.

### DETAILED DESCRIPTION OF EMBODIMENTS

Hereinafter, an exemplary embodiment of the present disclosure will be described in detail using the drawings. It is noted that any embodiment described below illustrates a comprehensive or specific example. Numerical values, shapes, materials, constituents, a disposition and a connection form of the constituents, and the like illustrated in the following embodiment are examples and not intended to limit the present disclosure.

Each drawing is a schematic diagram that is highlighted, omitted, or adjusted in ratio, as appropriate, to illustrate the present disclosure and is not necessarily illustrated in a strict sense. Each drawing may have different shapes, positional relationships, and ratios from those in actuality. Substantially the same configurations are designated by the same reference signs in each drawing, and duplicate descriptions may be omitted or simplified.

In each drawing below, an x-axis and a y-axis are axes that are orthogonal to each other on a plane parallel to a main surface of a module laminate. For example, in a case where the module laminate has a rectangular shape in a plan view, the x-axis is parallel to a first edge of the module laminate, and the y-axis is parallel to a second edge of the module laminate that is orthogonal to the first edge. In addition, a z-axis is an axis perpendicular to the main surface of the module laminate. A positive direction of the z-axis indicates an upward direction, and a negative direction of the z-axis indicates a downward direction.

In addition, in the following embodiment, the term “connected” includes not only a case of being directly connected through a connection terminal and/or a wire conductor but also a case of being electrically connected through other circuit elements. Moreover, for purposes of this disclosure, the expression “connected between A and B” means being connected to both A and B directly through a connection terminal and/or a wire conductor or means being connected to both A and B indirectly through a connection path connecting A to B.

In addition, in the component disposition of the present disclosure, the expression “A is disposed on the main surface of the laminate” not only means that A is directly mounted on the main surface but also means that A is disposed in a space on the main surface side out of the space on the main surface side and a space on a side opposite to the main surface divided by the laminate. That is, mounting A on the main surface with other circuit components, electrodes, and the like interposed therebetween is included.

In addition, in the component disposition of the present disclosure, the term “plan view” means viewing an object orthogonally projected to an xy plane from a positive side of the z-axis.

In addition, in the component disposition of the present disclosure, the expression “A and B are adjacent to each other” means that A and B are disposed close to each other. For example, this means that a circuit component is not present in a space in which A and B face each other. In other words, this means that any of a plurality of line segments that reach B along a direction normal to a surface of A facing B from any point on the surface does not pass through a circuit component other than A and B. The circuit component includes active components such as a transistor and a diode and passive components such as an inductor, a transformer, a capacitor, and a resistor and does not include a terminal, a connector, an electrode, a wire, a resin member, and the like.

In addition, in the present disclosure, terms such as “parallel” and “perpendicular” indicates a relationship between elements, and terms such as “rectangular” indicates a shape of an element which not only represents a strict meaning but also means that a substantially equivalent range including, for example, an error of approximately a few % is included.

In addition, in the present disclosure, the term “signal path” means a transmission line configured with a wire through which a radio frequency signal propagates, an electrode directly connected to the wire, a terminal directly connected to the wire or to the electrode, and the like.

### 1 Circuit Configuration of Power Supply Circuit 1 and Communication Device 7

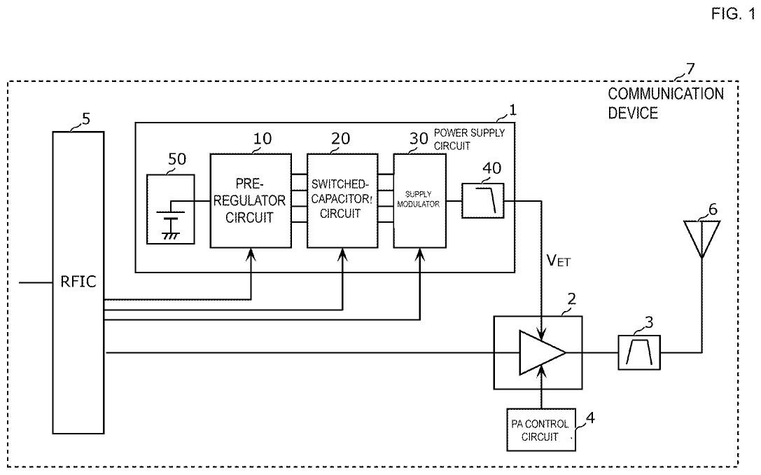

Circuit configurations of a power supply circuit 1 and a communication device 7 according to the present disclosure will be described with reference to FIG. 1. FIG. 1 is a circuit block diagram of the power supply circuit 1 and the communication device 7 according to the disclosure.

### 1.1 Circuit Configuration of Communication Device 7

As illustrated in FIG. 1, the communication device 7 according to the present disclosure includes the power supply circuit 1, a power amplifier circuit 2, a filter 3, a PA control circuit 4, a radio frequency integrated circuit (RFIC) 5, and an antenna 6.

In an exemplary aspect, the power supply circuit 1 includes a pre-regulator circuit 10, a switched-capacitor circuit 20, a supply modulator 30, a filter circuit 40, and a direct current power source 50.

The power supply circuit 1 supplies a power supply voltage V_{ET} having a power supply voltage level selected from a plurality of discrete voltage levels based on an envelope signal to the power amplifier circuit 2. In FIG. 1, one power supply circuit, such as the power supply circuit 1, supplies one power supply voltage V_{ET} to one power amplifier circuit, such as the power amplifier circuit 2. However, in FIG. 1, a plurality of power supply voltages may be individually supplied to a plurality of power amplifiers.

The pre-regulator circuit 10 is an example of a third circuit (e.g., a converter circuit) and includes a power inductor and a switch. The power inductor is an inductor used for stepping up and/or stepping down a direct current voltage. The power inductor is disposed in series on a direct current path. The pre-regulator circuit 10 can convert an input voltage (e.g., a third voltage) into a first voltage using the power inductor. The pre-regulator circuit 10 may be referred to as a magnetic regulator or a direct current (DC)/DC converter. The power inductor may be connected (e.g., disposed in parallel) between a series path and a ground.

In an exemplary aspect, the pre-regulator circuit 10 not including a power inductor may be used. For example, the pre-regulator circuit 10 may be a circuit that executes the step-up by switching between capacitors disposed on each of a series arm path and a parallel arm path of the pre-regulator circuit 10.

The switched-capacitor circuit 20 is an example of a first circuit and includes a plurality of capacitors and a plurality of switches. The switched-capacitor circuit 20 can generate a plurality of second voltages including the plurality of discrete voltage levels, respectively, from the first voltage generated from the pre-regulator circuit 10. The switched-capacitor circuit 20 may be referred to as a switched-capacitor voltage balancer.

The supply modulator 30 is an example of a second circuit and can selectively output at least one of a plurality of discrete voltages (e.g., the plurality of second voltages) generated by the switched-capacitor circuit 20 to the filter circuit 40 based on a digital control signal corresponding to the envelope signal. Consequently, at least one voltage selected from the plurality of discrete voltages is output from the supply modulator 30. The supply modulator 30 can change the output voltage over time by repeating selection of the voltage over time.

The supply modulator 30 may include various circuit elements and/or wires that cause a voltage drop and/or a noise and the like. Thus, a time waveform of the output voltage of the supply modulator 30 may not be a rectangular wave and may only include the plurality of discrete voltages. That is, the output voltage of the supply modulator 30 may include a voltage different from the plurality of discrete voltages.

The filter circuit 40 is an example of a fourth circuit and can filter signals (e.g., second voltages) from the supply modulator 30. The filter circuit 40 is configured with, for example, a low pass filter (LPF).

The direct current power source 50 can supply a direct current voltage to the pre-regulator circuit 10. For example, a rechargeable battery can be used as the direct current power source 50. However, the direct current power source 50 is not limited thereto.

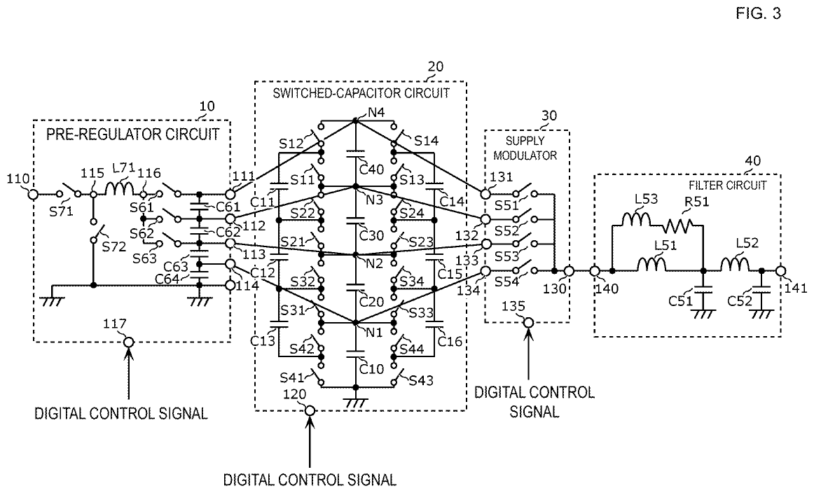

In an exemplary aspect, the power supply circuit 1 may not include one of the pre-regulator circuit 10, the filter circuit 40, and the direct current power source 50. For example, the power supply circuit 1 may not include the filter circuit 40 and the direct current power source 50. In addition, any combination of the pre-regulator circuit 10, the switched-capacitor circuit 20, the supply modulator 30, and the filter circuit 40 may be integrated into a single circuit. A detailed circuit configuration example of the power supply circuit 1 will be described later using FIG. 3.

The power amplifier circuit 2 is connected (or coupled) between the RFIC 5 and the filter 3, amplifies a radio frequency transmission signal (hereinafter, referred to as a transmission signal) of a predetermined band output from the RFIC 5, and outputs the amplified transmission signal to the antenna 6 through the filter 3.

The PA control circuit 4 receives a control signal from the RFIC 5 to control a magnitude and a supply timing of a bias current (or a bias voltage) that is to be supplied to the power amplifier circuit 2.

As illustrated in FIG. 1, the filter 3 is connected (or coupled) between the power amplifier circuit 2 and the antenna 6. The filter 3 has a passband including the predetermined band. Accordingly, the transmission signal of the predetermined band amplified by the power amplifier circuit 2 can pass through the filter 3.

The antenna 6 is connected to an output side of the power amplifier circuit 2 and transmits the transmission signal of the predetermined band output from the power amplifier circuit 2.

The RFIC 5 is an example of a signal processing circuit that processes a radio frequency signal. For example, the RFIC 5 performs signal processing such as upconversion on a transmission signal input from a baseband signal processing circuit (e.g., BBIC; not illustrated) and outputs the transmission signal generated through the signal processing to the power amplifier circuit 2.

In addition, the RFIC 5 is an example of a control circuit and includes a control unit that controls the power supply circuit 1 and the power amplifier circuit 2. The RFIC 5 causes the supply modulator 30 to select the voltage level of the power supply voltage V_{ET} from the plurality of discrete voltage levels. The power supply voltage V_{ET} can be used in the power amplifier circuit 2. The plurality of discrete voltage levels can be generated by the switched-capacitor circuit 20 based on the envelope signal of the radio frequency input signal obtained from the BBIC. Accordingly, the power supply circuit 1 outputs the power supply voltage V_{ET} based on digital envelope tracking.

A part or all of functions of the RFIC 5 as the control unit may be present outside the RFIC 5. For example, the part or all of functions of the RFIC 5 may be provided in the BBIC or the power supply circuit 1. In an example, a control function of selecting the power supply voltage V_{ET} may be provided in the power supply circuit 1 instead of the RFIC 5.

The envelope signal is a signal indicating an envelope of the radio frequency input signal (modulated signal). An envelope value is represented by, for example, √(i₂+Q₂). Here, (I, Q) represents a constellation point. The constellation point is a point representing a signal modulated by digital modulation on a constellation diagram. (I, Q) is determined by the BBIC based on, for example, transmission information.

Tracking the envelope of the radio frequency signal using the plurality of discrete voltage levels in one frame is referred to as the digital envelope tracking (hereinafter, referred to as digital ET), and a mode in which the digital ET is applied to the power supply voltage is referred to as a digital ET mode. In addition, tracking the envelope of the radio frequency signal using a continuous voltage level is referred to as analog envelope tracking (hereinafter, referred to as analog ET), and a mode in which the analog ET is applied to the power supply voltage is referred to as an analog ET mode.

The frame represents a unit forming the radio frequency signal (e.g., a modulated signal). For example, in 5th Generation New Radio (5G NR) and Long Term Evolution (LTE), the frame has 10 subframes, each subframe has a plurality of slots, and each slot is configured with a plurality of symbols. A subframe length is 1 ms, and a frame length is 10 ms.

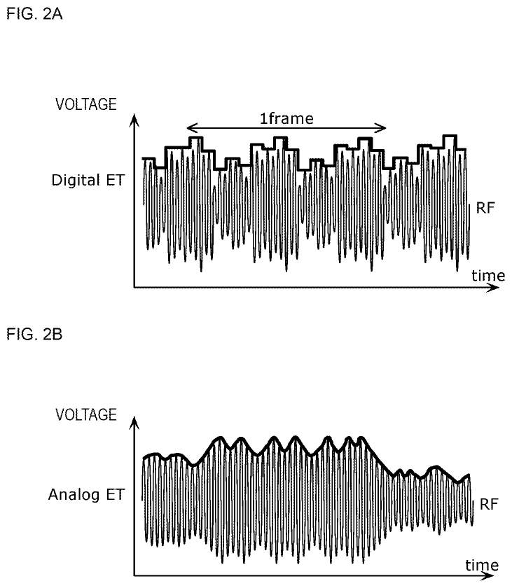

In the disclosure, the digital ET mode and the analog ET mode will be described with reference to FIGS. 2A and 2B.

FIG. 2A is a graph illustrating an example of transition of the power supply voltage in the digital ET mode. FIG. 2B is a graph illustrating an example of transition of the power supply voltage in the analog ET mode. In FIGS. 2A and 2B, a horizontal axis represents time, and a vertical axis represents a voltage. In addition, a thick solid line represents the power supply voltage V_{ET}, and a thin solid line (waveform) represents the modulated signal.

In the digital ET mode, as illustrated in FIG. 2A, the envelope of the modulated signal is tracked by changing the power supply voltage V_{ET} to the plurality of discrete voltage levels in one frame. Consequently, a power supply voltage signal forms a rectangular wave. In the digital ET mode, the power supply voltage level is selected from the plurality of discrete voltage levels based on the envelope signal (√(i₂+Q₂)).

In the analog ET mode, as illustrated in FIG. 2B, the envelope of the modulated signal is tracked by continuously changing the power supply voltage V_{ET}. In the analog ET mode, the power supply voltage V_{ET} is determined based on the envelope signal. In the analog ET, the power supply voltage V_{ET} can follow the change in the envelope of the modulated signal in a case where a channel band width is relatively small (for example, less than 60 MHz). However, in a case where the channel band width is relatively large (for example, 60 MHz or greater), the power supply voltage V_{ET} cannot follow the change in the envelope of the modulated signal. In other words, in a case where the channel band width is relatively large, a change in an amplitude of the power supply voltage V_{ET} is delayed with respect to the change in the envelope of the modulated signal.

In an exemplary aspect, in a case where the channel band width is relatively large (for example, 60 MHz or greater), ability of the power supply voltage V_{ET} to follow the modulated signal is improved by applying the digital ET mode, as illustrated in FIG. 2A.

The communication device 7 illustrated in FIG. 1 is an example, and the present disclosure is not limited thereto. For example, the communication device 7 may not include the filter 3, the PA control circuit 4, and the antenna 6. Furthermore, the communication device 7 may include a low-noise amplifier and a receive path including a receive filter. In addition, for example, the communication device 7 may include a plurality of power amplifier circuits corresponding to different bands.

### 1.2 Circuit Configuration of Power Supply Circuit 1

In an exemplary aspect, circuit configurations of the pre-regulator circuit 10, the switched-capacitor circuit 20, the supply modulator 30, and the filter circuit 40 included in the power supply circuit 1 will be described with reference to FIG. 3. FIG. 3 is a diagram illustrating a circuit configuration example of the power supply circuit 1 according to an exemplary embodiment of the disclosure.

FIG. 3 is an exemplary circuit configuration, and the pre-regulator circuit 10, the switched-capacitor circuit 20, the supply modulator 30, and the filter circuit 40 may be mounted using any of various circuit mounting and circuit technologies. Accordingly, description of each circuit provided below is not to be interpreted as being limiting.

### 1.2.1 Circuit Configuration of Switched-Capacitor Circuit 20

The circuit configuration of the switched-capacitor circuit 20 can be provided in FIG. 3. As illustrated in FIG. 3, the switched-capacitor circuit 20 includes capacitors C11, C12, C13, C14, C15, C16, C10, C20, C30, and C40, switches S11, S12, S13, S14, S21, S22, S23, S24, S31, S32, S33, S34, S41, S42, S43, and S44, and a control terminal 120. It should be noted that FIG. 3 is merely an example. The switched-capacitor circuit 20 can include any other capacitors, switches, or components.

The control terminal 120 is an input terminal of the digital control signal. In an aspect, the control terminal 120 is a terminal for receiving the digital control signal to control the switched-capacitor circuit 20. For example, a control signal of a source-synchronous scheme for transmitting a data signal and a clock signal can be used as the digital control signal received through the control terminal 120. However, the digital control signal is not limited thereto. For example, a clock-embedded scheme may be applied to the digital control signal.

Each of the capacitors C11 to C16 functions as a flying capacitor (may be referred to as a transfer capacitor). In an example, each of the capacitors C11 to C16 is used for stepping up or stepping down the first voltage supplied from the pre-regulator circuit 10. In an example, the capacitors C11 to C16 cause charges to move between the capacitors C11 to C16 and nodes N1 to N4 such that voltages V1 to V4 (e.g., voltages with respect to a ground potential) satisfying V1:V2:V3:V4=1:2:3:4 are maintained among the four nodes N1 to N4. Each of the voltages V1 to V4 corresponding to the plurality of second voltages can have a respective one of the plurality of discrete voltage levels (or respective discrete voltage level).

The capacitor C11 includes two electrodes. One of the two electrodes of the capacitor C11 is connected to one end of the switch S11 and one end of the switch S12. Another of the two electrodes of the capacitor C11 is connected to one end of the switch S21 and one end of the switch S22. For purposes of this disclosure the term “one end” may generally be considered a “first end” and the term “another end” or the “other end” may generally be considered a “second end”.

The capacitor C12 is an example of a first capacitor and includes two electrodes (e.g., a first electrode and a second electrode). One of the two electrodes of the capacitor C12 is connected to one end of the switch S21 and one end of the switch S22. The other of the two electrodes of the capacitor C12 is connected to one end of the switch S31 and one end of the switch S32.

The capacitor C13 includes two electrodes. One of the two electrodes of the capacitor C13 is connected to one end of the switch S31 and one end of the switch S32. The other of the two electrodes of the capacitor C13 is connected to one end of the switch S41 and one end of the switch S42.

The capacitor C14 includes two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 is an example of a second capacitor and includes two electrodes (examples of a third electrode and a fourth electrode). One of the two electrodes of the capacitor C15 is connected to one end of the switch S23 and one end of the switch S24. The other of the two electrodes of the capacitor C15 is connected to one end of the switch S33 and one end of the switch S34.

The capacitor C16 includes two electrodes. One of the two electrodes of the capacitor C16 is connected to one end of the switch S33 and one end of the switch S34. The other of the two electrodes of the capacitor C16 is connected to one end of the switch S33 and one end of the switch S34.

The capacitors C11 and C13 are also examples of the first capacitor, and the capacitors C14 and C16 are also examples of the second capacitor.

Each of a set of the capacitors C11 and C14, a set of the capacitors C12 and C15, and a set of the capacitors C13 and C16 can be charged and discharged in a complementary manner by repeating a first phase and a second phase.

In an example, in the first phase, the switches S12, S13, S22, S23, S32, S33, S42, and S43 are ON. Accordingly, for example, one of the two electrodes of the capacitor C12 is connected to the node N3, the other of the two electrodes of the capacitor C12 and one of the two electrodes of the capacitor C15 are connected to the node N2, and the other of the two electrodes of the capacitor C15 is connected to the node N1.

In an exemplary aspect, in the second phase, the switches S11, S14, S21, S24, S31, S34, S41, and S44 are ON. Accordingly, for example, one of the two electrodes of the capacitor C15 is connected to the node N3, the other of the two electrodes of the capacitor C15 and one of the two electrodes of the capacitor C12 are connected to the node N2, and the other of the two electrodes of the capacitor C12 is connected to the node N1.

By repeating the first phase and the second phase, for example, one of the capacitors C12 and C15 can be discharged to the capacitor C30 while the other of the capacitors C12 and C15 is being charged from the node N2. That is, the capacitors C12 and C15 can be charged and discharged in a complementary manner. The capacitors C12 and C15 are a pair of flying capacitors that are charged and discharged in a complementary manner.

A set of any of the capacitors C11, C12, and C13 (e.g., a first capacitor) and any of C14, C15, and C16 (e.g., a second capacitor) is also a pair of flying capacitors like the set of the capacitors C12 and C15 that are charged from a node and discharged to a smoothing capacitor in a complementary manner by appropriately switching the switches.

Each of the capacitors C10, C20, C30, and C40 functions as a smoothing capacitor. That is, each of the capacitors C10, C20, C30, and C40 is used for holding and smoothing the voltages V1 to V4 in the nodes N1 to N4.

The capacitor C10 is an example of a third capacitor and is connected between the node N1 and the ground. In an example, one (e.g., a fifth electrode) of two electrodes of the capacitor C10 is connected to the node N1. In an example, the other (e.g., a sixth electrode) of the two electrodes of the capacitor C10 is connected to the ground.

The capacitor C20 is connected between the nodes N2 and N1. In an example, one of two electrodes of the capacitor C20 is connected to the node N2. In an example, the other of the two electrodes of the capacitor C20 is connected to the node N1.

The capacitor C30 is connected between the nodes N3 and N2. In an example, one of two electrodes of the capacitor C30 is connected to the node N3. In an example, one of the two electrodes of the capacitor C30 is connected to the node N2.

The capacitor C40 is connected between the nodes N4 and N3. In an example, one of two electrodes of the capacitor C40 is connected to the node N4. In an example, the other of the two electrodes of the capacitor C40 is connected to the node N3.

The switch S11 is connected between one of the two electrodes of the capacitor C11 and the node N3. In an example, one end of the switch S11 is connected to one of the two electrodes of the capacitor C11. In an example, the other end of the switch S11 is connected to the node N3.

The switch S12 is connected between one of the two electrodes of the capacitor C11 and the node N4. In an example, one end of the switch S12 is connected to one of the two electrodes of the capacitor C11. In an example, the other end of the switch S12 is connected to the node N4.

The switch S21 is an example of a first switch and is connected between one of the two electrodes of the capacitor C12 and the node N2. In an example, one end of the switch S21 is connected to one of the two electrodes of the capacitor C12 and the other of the two electrodes of the capacitor C11. In an example, the other end of the switch S21 is connected to the node N2.

The switch S22 is an example of a third switch and is connected between one of the two electrodes of the capacitor C12 and the node N3. In an example, one end of the switch S22 is connected to one of the two electrodes of the capacitor C12 and the other of the two electrodes of the capacitor C11. In an example, the other end of the switch S22 is connected to the node N3.

The switch S31 is an example of a fourth switch and is connected between the other of the two electrodes of the capacitor C12 and the node N1. In an example, one end of the switch S31 is connected to the other of the two electrodes of the capacitor C12 and one of the two electrodes of the capacitor C13. In an example, the other end of the switch S31 is connected to the node N1.

The switch S32 is an example of a second switch and is connected between the other of the two electrodes of the capacitor C12 and the node N2. In an example, one end of the switch S32 is connected to the other of the two electrodes of the capacitor C12 and one of the two electrodes of the capacitor C13. In an example, the other end of the switch S32 is connected to the node N2. That is, the other end of the switch S32 is connected to the other end of the switch S21.

The switch S41 is connected between the other of the two electrodes of the capacitor C13 and the ground. In an example, one end of the switch S41 is connected to the other of the two electrodes of the capacitor C13. In an example, the other end of the switch S41 is connected to the ground.

The switch S42 is connected between the other of the two electrodes of the capacitor C13 and the node N1. In an example, one end of the switch S42 is connected to the other of the two electrodes of the capacitor C13. In an example, the other end of the switch S42 is connected to the node N1. That is, the other end of the switch S42 is connected to the other end of the switch S31.

The switch S13 is connected between one of the two electrodes of the capacitor C14 and the node N3. In an example, one end of the switch S13 is connected to one of the two electrodes of the capacitor C14. In an example, the other end of the switch S13 is connected to the node N3. That is, the other end of the switch S13 is connected to the other end of the switch S11 and the other end of the switch S22.

The switch S14 is connected between one of the two electrodes of the capacitor C14 and the node N4. In an example, one end of the switch S14 is connected to one of the two electrodes of the capacitor C14. In an example, the other end of the switch S14 is connected to the node N4. That is, the other end of the switch S14 is connected to the other end of the switch S12.

The switch S23 is an example of a fifth switch and is connected between one of the two electrodes of the capacitor C15 and the node N2. In an example, one end of the switch S23 is connected to one of the two electrodes of the capacitor C15 and the other of the two electrodes of the capacitor C14. In an example, the other end of the switch S23 is connected to the node N2. That is, the other end of the switch S23 is connected to the other end of the switch S21 and the other end of the switch S32.

The switch S24 is an example of a seventh switch and is connected between one of the two electrodes of the capacitor C15 and the node N3. In an example, one end of the switch S24 is connected to one of the two electrodes of the capacitor C15 and the other of the two electrodes of the capacitor C14. In an example, the other end of the switch S24 is connected to the node N3. That is, the other end of the switch S24 is connected to the other end of the switch S11, the other end of the switch S22, and the other end of the switch S13.

The switch S33 is an example of an eighth switch and is connected between one of the two electrodes of the capacitor C15 and the node N1. In an example, one end of the switch S33 is connected to the other of the two electrodes of the capacitor C15 and one of the two electrodes of the capacitor C16. In an example, the other end of the switch S33 is connected to the node N1. That is, the other end of the switch S33 is connected to the other end of the switch S31 and the other end of the switch S42.

The switch S34 is an example of a sixth switch and is connected between the other of the two electrodes of the capacitor C15 and the node N2. In an example, one end of the switch S34 is connected to the other of the two electrodes of the capacitor C15 and one of the two electrodes of the capacitor C16. In an example, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. In an example, one end of the switch S43 is connected to the other of the two electrodes of the capacitor C16. In an example, the other end of the switch S43 is connected to the ground.

The switch S44 is connected between the other of the two electrodes of the capacitor C16 and the node N1. In an example, one end of the switch S44 is connected to the other of the two electrodes of the capacitor C16. In an example, the other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched ON and OFF in a complementary manner. In an example, in the first phase, the first set of switches is ON, and the second set of switches is OFF. Conversely, in the second phase, the first set of switches is OFF, and the second set of switches is ON.

For example, charging of the capacitors C10 to C40 from the capacitors C11 to C13 is executed in one of the first phase and the second phase, and charging of the capacitors C10 to C40 from the capacitors C14 to C16 is executed in the other of the first phase and the second phase. That is, the capacitors C10 to C40 are always charged from the capacitors C11 to C13 or from the capacitors C14 to C16. Thus, even in a case where a current flows at a high speed from the nodes N1 to N4 to the supply modulator 30, a change in potentials of the nodes N1 to N4 can be suppressed because the nodes N1 to N4 are supplemented with charges at a high speed.

The switched-capacitor circuit 20, by operating in the above manner, can maintain almost equal voltages at both ends of each of the capacitors C10, C20, C30, and C40. In an example, the voltages V1 to V4 (voltages with respect to the ground potential) satisfying V1:V2:V3:V4=1:2:3:4 are maintained in four nodes labeled V1 to V4. The voltage levels of the voltages V1 to V4 correspond to the plurality of discrete voltage levels supplied to the supply modulator 30 by the switched-capacitor circuit 20.

The voltage ratio V1:V2:V3:V4 is not limited to 1:2:3:4. For example, the voltage ratio V1:V2:V3:V4 may be 1:2:4:8.

In addition, the configuration of the switched-capacitor circuit 20 illustrated in FIG. 3 is an example, and the present disclosure is not limited thereto. While the switched-capacitor circuit 20 is configured to supply voltages of four discrete voltage levels in FIG. 3, the switched-capacitor circuit 20 is not limited thereto. The switched-capacitor circuit 20 may be configured to supply voltages of any number of discrete voltage levels of two or more. For example, in a case where voltages of two discrete voltage levels are supplied, the switched-capacitor circuit 20 may include at least the capacitors C12 and C15 and the switches S21, S22, S31, S32, S23, S24, S33, and S34.

### 1.2.2 Circuit Configuration of Supply Modulator 30

Still referring to FIG. 3, the circuit configuration of the supply modulator 30 can be described as follows. As illustrated in FIG. 3, the supply modulator 30 includes input terminals 131 to 134, switches S51, S52, S53, and S54, an output terminal 130, and a control terminal 135.

The output terminal 130 is connected to the filter circuit 40. The output terminal 130 is a terminal for supplying at least one voltage selected from the voltages V1 to V4 as the power supply voltage V_{ET} to the power amplifier circuit 2 through the filter circuit 40. As described above, the supply modulator 30 may include various circuit elements and/or wires that cause a voltage drop and/or a noise and the like. Thus, the power supply voltage V_{ET} observed at the output terminal 130 may include a voltage different from the voltages V1 to V4.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20.

The control terminal 135 is an input terminal of the digital control signal. That is, the control terminal 135 is a terminal for receiving the digital control signal indicating one of the voltages V1 to V4. The supply modulator 30 controls the switches S51 to S54 to be ON/OFF such that the voltage level indicated by the digital control signal is selected.

Two digital control line/logic (DCL) signals can be used as the digital control signal received through the control terminal 135. Each of the two DCL signals is a 1-bit signal. One of the voltages V1 to V4 is indicated by a combination of two 1-bit signals. For example, V1, V2, V3, and V4 are indicated by “00”, “01”, “10”, and “11”, respectively. A gray code may be used for representing the voltage level. In this case, since two DCL signals are received, two control terminals are provided. In addition, any number of one or more may be used as the number of DCL signals in accordance with the number of voltage levels. In addition, the DCL signal may be a signal of 2 bits or more. In addition, the digital control signal may be one or more DCL signals, and the control signal of the source-synchronous scheme may be used as the digital control signal.

The switch S51 is connected between the input terminal 131 and the output terminal 130. In an example, the switch S51 includes a terminal connected to the input terminal 131 and a terminal connected to the output terminal 130. In this connection configuration, the switch S51 can be switched ON/OFF to switch between a connected state and a non-connected state between the input terminal 131 and the output terminal 130.

The switch S52 is an example of a tenth switch and is connected between the input terminal 132 and the output terminal 130. In an example, the switch S52 includes a terminal connected to the input terminal 132 and a terminal connected to the output terminal 130. In this connection configuration, the switch S52 can be switched ON/OFF to switch between a connected state and a non-connected state between the input terminal 132 and the output terminal 130.

The switch S53 is an example of a ninth switch and is connected between the input terminal 133 and the output terminal 130. In an example, the switch S53 includes a terminal connected to the input terminal 133 and a terminal connected to the output terminal 130. In this connection configuration, the switch S53 can be switched ON/OFF to switch between a connected state and a non-connected state between the input terminal 133 and the output terminal 130.

The switch S54 is connected between the input terminal 134 and the output terminal 130. In an example, the switch S54 includes a terminal connected to the input terminal 134 and a terminal connected to the output terminal 130. In this connection configuration, the switch S54 can be switched ON/OFF to switch between a connected state and a non-connected state between the input terminal 134 and the output terminal 130.

The switches S51 to S54 are controlled to be exclusively ON. That is, only one of the switches S51 to S54 is ON, and the rest of the switches S51 to S54 is OFF. Accordingly, the supply modulator 30 can output one voltage selected from the voltages V1 to V4.

The configuration of the supply modulator 30 illustrated in FIG. 3 is an example, and the present disclosure is not limited thereto. Particularly, the switches S51 to S54 may have any configurations as long as any of the four input terminals 131 to 134 can be selected and connected to the output terminal 130. For example, the supply modulator 30 may further include a switch connected between the switches S51 to S53, and the switch S54 and the output terminal 130. In addition, for example, the supply modulator 30 may further include a switch connected between the switches S51 and S52, and the switches S53 and S54 and the output terminal 130.

In addition, for example, in the case of selecting one voltage from the second voltages of two discrete voltage levels, the supply modulator 30 may include at least the switches S52 and S53.

In addition, the supply modulator 30 may be configured to output two or more voltages. In this case, the supply modulator 30 may further include a necessary number of additional switch sets like the set of switches S51 to S54 and a necessary number of additional output terminals.

### 1.2.3 Circuit Configuration of Pre-Regulator Circuit 10

Still referring to FIG. 3, the circuit configuration of the pre-regulator circuit 10 can be described. As illustrated in FIG. 3, the pre-regulator circuit 10 includes an input terminal 110, output terminals 111 to 114, inductor connection terminals 115 and 116, a control terminal 117, switches S61, S62, S63, S71, and S72, a power inductor L71, and capacitors C61, C62, C63, and C64.

The input terminal 110 is an example of a third input terminal and is an input terminal of a direct current voltage. That is, the input terminal 110 is a terminal for receiving the input voltage from the direct current power source 50.

The output terminal 111 is an output terminal of the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal of the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal of the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal of the voltage V1. That is, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The control terminal 117 is an input terminal of the digital control signal. That is, the control terminal 117 is a terminal for receiving the digital control signal for controlling the pre-regulator circuit 10.

The switch S71 is an example of an eleventh switch and is connected between the input terminal 110 and one end of the power inductor L71. In an example, the switch S71 includes a terminal connected to the input terminal 110 and a terminal connected to one end of the power inductor L71 through the inductor connection terminal 115. In this connection configuration, the switch S71 can be switched ON/OFF to switch between a connected state and a non-connected state between the input terminal 110 and one end of the power inductor L71.

The switch S72 is an example of a twelfth switch and is connected between one end of the power inductor L71 and the ground. In an example, the switch S72 includes a terminal connected to one end of the power inductor L71 through the inductor connection terminal 115 and a terminal connected to the ground. In this connection configuration, the switch S72 can be switched ON/OFF to switch between a connected state and a non-connected state between one end of the power inductor L71 and the ground.

The switch S61 is connected between the other end of the power inductor L71 and the output terminal 111. In an example, the switch S61 includes a terminal connected to the other end of the power inductor L71 and a terminal connected to the output terminal 111. In this connection configuration, the switch S61 can be switched ON/OFF to switch between a connected state and a non-connected state between the other end of the power inductor L71 and the output terminal 111.

The switch S62 is connected between the other end of the power inductor L71 and the output terminal 112. In an example, the switch S62 includes a terminal connected to the other end of the power inductor L71 and a terminal connected to the output terminal 112. In this connection configuration, the switch S62 can be switched ON/OFF to switch between a connected state and a non-connected state between the other end of the power inductor L71 and the output terminal 112.

The switch S63 is connected between the other end of the power inductor L71 and the output terminal 113. In an example, the switch S63 includes a terminal connected to the other end of the power inductor L71 and a terminal connected to the output terminal 113. In this connection configuration, the switch S63 can be switched ON/OFF to switch between a connected state and a non-connected state between the other end of the power inductor L71 and the output terminal 113.

The capacitor C61 is connected between the output terminal 111 and the output terminal 112. One of two electrodes of the capacitor C61 is connected to the switch S61 and the output terminal 111, and the other of the two electrodes of the capacitor C61 is connected to the switch S62, the output terminal 112, and one of two electrodes of the capacitor C62.

The capacitor C62 is connected between the output terminal 112 and the output terminal 113. One of the two electrodes of the capacitor C62 is connected to the switch S62, the output terminal 112, and the other of the two electrodes of the capacitor C61, and the other of the two electrodes of the capacitor C62 is connected to a path connecting the switch S63, the output terminal 113, and one of two electrodes of the capacitor C63.

The capacitor C63 is an example of a fourth capacitor and is connected between the output terminal 113 and the output terminal 114. One of two electrodes of the capacitor C63 is connected to the switch S63, the output terminal 113, and the other of the two electrodes of the capacitor C62, and the other of the two electrodes of the capacitor C63 is connected to the output terminal 114 and one of two electrodes of the capacitor C64.

The capacitor C64 is connected between the output terminal 114 and the ground. One of the two electrodes of the capacitor C64 is connected to the output terminal 114 and the other of the two electrodes of the capacitor C63, and the other of the two electrodes of the capacitor C64 is connected to the ground.

The switches S61 to S63 are controlled to be exclusively ON. That is, only one of the switches S61 to S63 is ON, and the rest of the switches S61 to S63 is OFF. By causing only one of the switches S61 to S63 to be ON, the pre-regulator circuit 10 can change the voltage to be supplied to the switched-capacitor circuit 20 among the voltage levels of the voltages V2 to V4.

The pre-regulator circuit 10 configured in the above manner supplies charges to the switched-capacitor circuit 20 through at least one of the output terminals 111 to 113.

In the case of converting the input voltage (third voltage) into one first voltage, the pre-regulator circuit 10 may include at least the switches S71 and S72 and the power inductor L71.

### 1.2.4 Circuit Configuration of Filter Circuit 40

Still referring to FIG. 3, the circuit configuration of the filter circuit 40 can be described as follows. As illustrated in FIG. 3, the filter circuit 40 includes inductors L51, L52, and L53, capacitors C51 and C52, a resistor R51, an input terminal 140, and an output terminal 141.

The input terminal 140 is an input terminal of the second voltage selected by the supply modulator 30. That is, the input terminal 140 is a terminal for receiving the second voltage selected from the plurality of voltages V1 to V4.

The output terminal 141 is an output terminal of the power supply voltage V_{ET}. That is, the output terminal 141 is a terminal for supplying the power supply voltage V_{ET} to the power amplifier circuit 2.

The inductor L51 and the inductor L52 are connected in series to each other between the input terminal 140 and the output terminal 141. A series connection circuit of the inductor L53 and the resistor R51 is connected in parallel to the inductor L51. The capacitor C51 is connected between a connection point between the inductors L51 and L52 and the ground. The capacitor C52 is connected between the output terminal 141 and the ground.

In the above configuration, the filter circuit 40 forms an LC low pass filter in which an inductor is disposed on a series arm path and a capacitor is disposed on a parallel arm path. Accordingly, the filter circuit 40 can reduce a radio frequency component included in the power supply voltage. For example, in a case where the predetermined band is a frequency band for frequency division duplex (FDD), the filter circuit 40 is configured to reduce a component of a downlink operation band of the predetermined band.

It should be appreciated that the configuration of the filter circuit 40 illustrated in FIG. 3 is an example, and the present disclosure is not limited thereto. The filter circuit 40 can form a band pass filter or a high pass filter depending on a band to be removed.

In addition, the filter circuit 40 may include two or more LC filters. The two or more LC filters may be connected in common to the output terminal 130, and each LC filter may have a passband or an attenuation band corresponding to each of different bands. Alternatively, a first filter group configured with two or more LC filters may be connected to a first output terminal of the supply modulator 30, a second filter group configured with another two or more LC filters may be connected to a second output terminal of the supply modulator 30, and each LC filter may have a passband or an attenuation band corresponding to each of different bands. In this case, the filter circuit 40 may include two or more output terminals and output two or more power supply voltages V_{ET} to the power amplifier circuit 2 at the same time.

Here, in the case of configuring the tracker module in which each switch of the switched-capacitor circuit 20 and each switch of the supply modulator 30 or the pre-regulator circuit 10 are mounted on the module laminate as different switch integrated circuits, wires connecting the switches and the capacitors of the switched-capacitor circuit 20 are expected to be long. Large currents caused by high-speed charging and discharging of the capacitors flow through the wires because of the application of the digital ET. Thus, the wires are required to have low resistance for the large currents to flow. However, in a case where the wires are long, a resistance loss in the wires is increased. In addition, in a case where the wires are made thick to avoid the resistance loss, impedance is shifted, and an output waveform of the power supply voltage V_{ET} (output characteristics of the power supply voltage) output from the tracker module may deteriorate.

### 2 Disposition Configuration of Components of Tracker Module

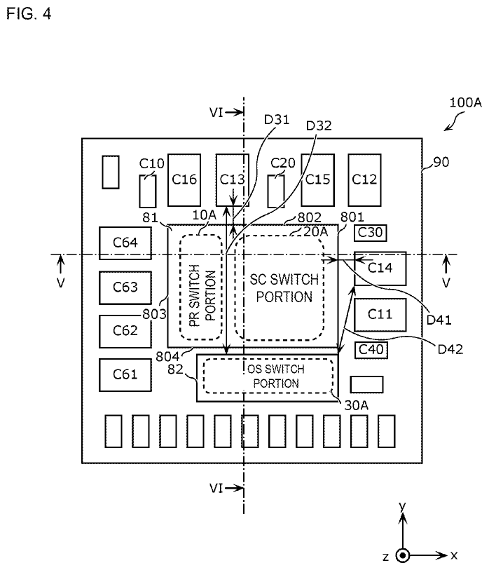

FIGS. 4-6 show an exemplary configuration for suppressing deterioration of the output characteristics of the power supply voltage V_{ET} in the tracker module on which the power supply circuit 1 according to the present disclosure is mounted.

### 2.1 Disposition Configuration of Components of Tracker Module 100A According to Example 1

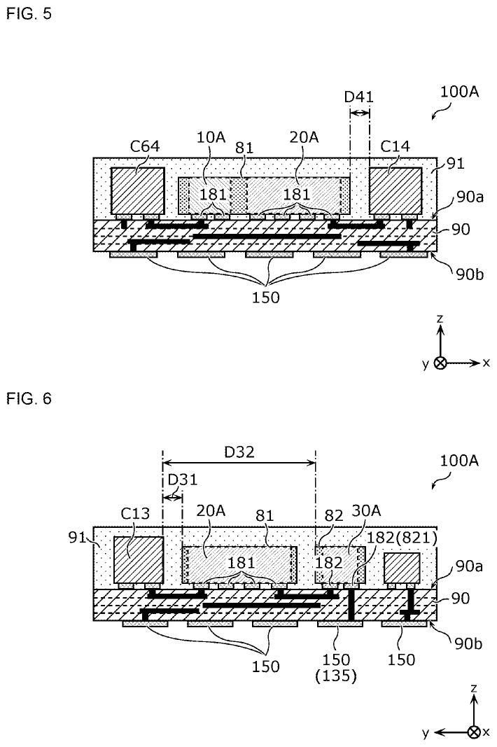

As shown in FIG. 4, a plan view of a tracker module 100A according to Example 1 is provided. FIG. 5 is a first cross-sectional view of the tracker module 100A according to Example 1. In an example, FIG. 5 is a cross-sectional view taken along line V-V in FIG. 4. FIG. 6 is a second cross-sectional view of the tracker module 100A according to Example 1. In an example, FIG. 6 is a cross-sectional view taken along line VI-VI in FIG. 4. FIG. 4 illustrates a diagram of disposition of circuit components in a case where a main surface 90a out of main surfaces 90a and 90b of a module laminate 90 facing each other is viewed from a side in the positive direction of the z-axis.

The tracker module 100A according to the present example illustrates a disposition configuration of a part of each circuit component forming the power supply circuit 1 according to the exemplary embodiment in FIG. 4.

As illustrated in FIGS. 4 to 6, the tracker module 100A according to the present example includes the module laminate 90, integrated circuits 81 and 82, the capacitors C10, C20, C30, C40, C11, C12, C13, C14, C15, C16, C61, C62, C63, and C64, and a resin member 91.

The module laminate 90 has the main surface 90a and the main surface 90b facing each other and is a laminate on which the circuit components forming the tracker module 100A are mounted. For example, a low temperature co-fired ceramics (LTCC) laminate, a high temperature co-fired ceramics (HTCC) laminate, a component-embedded board, a laminate having a redistribution layer (RDL), or a printed circuit board having a laminated structure of a plurality of dielectric layers is used as the module laminate 90.

Each of the integrated circuits 81 and 82 is a semiconductor integrated circuit (IC). For example, the integrated circuits 81 and 82 are configured using a complementary metal oxide semiconductor (CMOS) and are manufactured through a silicon on insulator (SOI) process. Each of the integrated circuits 81 and 82 may be formed of at least one of GaAs, SiGe, or GaN. Semiconductor materials of the integrated circuits 81 and 82 are not limited to the above materials.

The integrated circuit 81 includes a PR switch portion 10A, an SC switch portion 20A, and a plurality of input-output electrodes 181.

The PR switch portion 10A is configured with switches included in the pre-regulator circuit 10. In an example, the PR switch portion 10A includes the switches S61, S62, S63, S71, and S72.

The SC switch portion 20A is configured with switches included in the switched-capacitor circuit 20. Specifically, the SC switch portion 20A includes the switches S11, S12, S13, S14, S21, S22, S23, S24, S31, S32, S33, S34, S41, S42, S43, and S44.

The integrated circuit 82 includes an OS switch portion 30A and a plurality of input-output electrodes 182.

The OS switch portion 30A is configured with switches included in the supply modulator 30. In an example, the OS switch portion 30A includes the switches S51, S52, S53, and S54.

The capacitors C10, C20, C30, C40, C11, C12, C13, C14, C15, and C16 are capacitors included in the switched-capacitor circuit 20. In addition, the capacitors C51 and C52 are capacitors included in the filter circuit 40. In addition, the capacitors C61, C62, C63, and C64 are capacitors included in the pre-regulator circuit 10.

The plurality of input-output electrodes 181 and 182 are electrically connected to a plurality of circuit components disposed on the main surface 90a, a plurality of external connection electrodes 150 disposed on the main surface 90b, or the like through a wire layer, a via conductor, or the like formed in the module laminate 90. The plurality of input-output electrodes 182 include an input electrode 821.

The input electrode 821 is an example of an input terminal and is connected to the RFIC 5 disposed outside the tracker module 100A through the external connection electrode 150 (control terminal 135).

The resin member 91 is disposed on the main surface 90a and covers the main surface 90a and a part of the circuit components forming the tracker module 100A. The resin member 91 has a function of securing reliability, such as mechanical strength and humidity resistance, of the circuit components forming the tracker module 100A. It is noted that the resin member 91 is not a component that is essential to the tracker module 100A according to the present example.

The tracker module 100A may include at least one of the capacitors included in the switched-capacitor circuit 20 among the capacitors C10 to C64. In addition, the SC switch portion 20A may include at least one of the switches S11 to S44, the OS switch portion 30A may include at least one of the switches S51 to S54, and the PR switch portion 10A may include at least one of the switches S61 to S72.

In a case where the PR switch portion 10A, the SC switch portion 20A, and the OS switch portion 30A are accommodated in one integrated circuit, heat dissipation of the tracker module is decreased. In an example, in the tracker module 100A according to the present example, the PR switch portion 10A, the SC switch portion 20A, and the OS switch portion 30A are disposed to be distributed between the two integrated circuits 81 and 82. Accordingly, heat dissipation of the tracker module 100A is improved.

In addition, the integrated circuit 81 may include the PR switch portion 10A and the SC switch portion 20A, and the integrated circuit 82 different from the integrated circuit 81 may include the OS switch portion 30A.

In addition, the external connection electrodes 150 are disposed on the main surface 90b. The tracker module 100A exchanges electric signals with the RFIC 5, the power amplifier circuit 2, and an external laminate disposed on a side of the tracker module 100A in the negative direction of the z-axis through the plurality of external connection electrodes 150. In addition, some of the plurality of external connection electrodes 150 are set to have the ground potential.

The external connection electrodes 150 may be a planar electrode as illustrated in FIGS. 5 and 6 or may be bump electrodes formed on the main surface 90b.

In addition, while illustration is not provided in FIG. 4, wires connecting each circuit component illustrated in FIG. 3 are formed inside the module laminate 90 and on the main surfaces 90a and 90b. In addition, the wires may be bonding wires of which both ends are joined to any of the main surfaces 90a and 90b and the circuit components or may be terminals, electrodes, or wires formed on surfaces of the circuit components.

As illustrated in FIG. 4, in the tracker module 100A, a distance D41 between the integrated circuit 81 and the capacitor C14 is shorter than a distance D42 between the integrated circuit 82 and the capacitor C14.

In the switched-capacitor circuit 20, the plurality of high-accuracy and stable second voltages can be supplied to the supply modulator 30 by repeating charging and discharging of the capacitors. Thus, it is desirable that charges can move through the wires connecting the capacitors of the switched-capacitor circuit 20 to the switches connected to the capacitors at a high speed with low resistance.

In addition, the switched-capacitor circuit 20 and the supply modulator 30 are in an adjacent relationship from a viewpoint of the circuit connection illustrated in FIG. 3, and the capacitor C14 is disposed close to the output switch diagram 30A from a viewpoint of wire resistance reduction. In an example, by disposing the capacitor C14 further closer to the SC switch portion 20A than the output switch portion 30A, wire resistance between the capacitor C14 and the SC switch portion 20A can be substantially reduced.

According to the above configuration, since the wire connecting the capacitor C14 to the switch of the SC switch portion 20A can be substantially shortened by making the distance D41 shorter than the distance D42, parasitic resistance and parasitic inductance of the wire in the switched-capacitor circuit 20 can be decreased. Thus, since the plurality of high-accuracy and stable second voltages can be supplied to the supply modulator 30 from the switched-capacitor circuit 20, deterioration of the output waveform of the power supply voltage V_{ET} (output characteristics of the power supply voltage) output from the tracker module 100A can be suppressed.

A capacitor of which a distance to the integrated circuit 81 is shorter than a distance to the integrated circuit 82 is not limited to the capacitor C14. A capacitor having such a relationship may be at least one of the capacitors C10 to C16 included in the switched-capacitor circuit 20. According to this configuration, since the wire connecting the capacitor of the switched-capacitor circuit 20 to the switch of the SC switch portion 20A can be shortened, parasitic resistance and parasitic inductance of the wire in the switched-capacitor circuit 20 can be decreased.

In addition, the integrated circuit 81 is adjacent to the capacitor C14. According to this configuration, since the wire connecting the capacitor C14 to the switch of the SC switch portion 20A can be shortened, parasitic resistance and parasitic inductance of the wire in the switched-capacitor circuit 20 can be decreased.

In addition, in the present example, the SC switch portion 20A of the integrated circuit 81 is adjacent to the capacitor C14. According to this configuration, since the wire connecting the capacitor C14 to the switch of the SC switch portion 20A can be further shortened, parasitic resistance and parasitic inductance of the wire in the switched-capacitor circuit 20 can be further decreased.

In the present example, the integrated circuit 81 is adjacent to the capacitor C14, which means that the integrated circuit 81 is disposed close to the capacitor C14 and a circuit component is not present in a space interposed between a side surface of the integrated circuit 81 and a side surface of the capacitor C14 facing each other. The circuit component includes active components such as a transistor and a diode and passive components such as an inductor, a transformer, a capacitor, and a resistor and does not include a terminal, a connector, an electrode, a wire, a resin member, and the like.

Any of the capacitors C11, C12, and C13 and any of the capacitors C14, C15, and C16 are a pair of flying capacitors that are charged and discharged in a complementary manner among the plurality of capacitors included in the switched-capacitor circuit 20. That is, the capacitor C14 is one of the pair of flying capacitors.

Thus, the wires connected to the flying capacitors have a larger amount of charge movement than the wires connected to the smoothing capacitors (capacitors C10, C20, C30, and C40). In an example, since the wires connected to the flying capacitors can be shortened, the high-accuracy and stable second voltages having high voltage levels can be supplied to the supply modulator 30 from the switched-capacitor circuit 20, and deterioration of the output waveform of the power supply voltage V_{ET} (output characteristics of the power supply voltage) output from the tracker module 100A can be effectively suppressed.

Furthermore, the capacitor of which the distance to the integrated circuit 81 is shorter than the distance to the integrated circuit 82 is desirably the capacitor C11 or C14.

The capacitors C11 and C14 are capacitors to which the highest potential (voltage V4) is applied among the plurality of capacitors included in the switched-capacitor circuit 20. Thus, the wire connected to the capacitor C11, and the wire connected to the capacitor C14 have the largest amount of charge movement. In an example, since the wires can be shortened, the high-accuracy and stable second voltages having high voltage levels can be supplied to the supply modulator 30 from the switched-capacitor circuit 20, and deterioration of the output waveform of the power supply voltage V_{ET} (output characteristics of the power supply voltage) output from the tracker module 100A can be effectively suppressed.

Furthermore, in the present example, as illustrated in FIG. 4, a distance D31 between the integrated circuit 81 and the capacitor C13 is shorter than a distance D32 between the integrated circuit 82 and the capacitor C13, in addition to that of the capacitor C14.

In a plan view of the module laminate 90, the integrated circuit 81 has a rectangular peripheral shape and has four edges 801, 802, 803, and 804. Here, the capacitor C14 is disposed to face the edge 801 (e.g., a first edge), and the capacitor C13 is disposed to face the edge 802 (e.g., a second edge).

According to this configuration, by disposing the capacitors C13 and C14 on different edges while shortening the wire connected to the capacitor C14 and the wire connected to the capacitor C13, heat generated from the two wires can be dissipated in a distributed manner. Thus, heat dissipation of the tracker module 100A is improved. A combination of two capacitors disposed to be distributed on two different edges of the integrated circuit 81 is not limited to the capacitors C14 and C13 and may be a combination of any two capacitors of the plurality of capacitors included in the switched-capacitor circuit 20.

In addition, as illustrated in FIG. 4, the distance D41 between the integrated circuit 81 and the capacitor C14 may be shorter than the distance D42 between the integrated circuit 82 and the capacitor C14, and a distance between the integrated circuit 81 and the capacitor C15 may be shorter than a distance between the integrated circuit 82 and the capacitor C15. Here, in the plan view of the module laminate 90, the capacitor C14 is disposed to face the edge 801 (e.g., a first edge), and the capacitor C15 is disposed to face the edge 802 (e.g., a second edge).

According to the exemplary embodiment of FIG. 4, by disposing the pair of flying capacitors on different edges while shortening two wires respectively connected to the pair of flying capacitors, heat generated from the two wires can be dissipated in a distributed manner. Thus, heat dissipation of the tracker module 100A is improved.

In addition, a distance between the integrated circuit 81 and one of the pair of flying capacitors may be shorter than a distance between the integrated circuit 82 and the one, and a distance between the integrated circuit 81 and a smoothing capacitor may be shorter than a distance between the integrated circuit 82 and the smoothing capacitor. Here, in the plan view of the module laminate 90, the one of the pair of flying capacitors may be disposed to face the edge 801 (e.g., a first edge), and the smoothing capacitor may be disposed to face the edge 802 (e.g., a second edge).

According to the exemplary embodiment of FIG. 4, by disposing the flying capacitors and the smoothing capacitor on different edges while shortening the wire connected to one of the pair of flying capacitors and the wire connected to the smoothing capacitor, heat generated from the two wires can be dissipated in a distributed manner. Thus, heat dissipation of the tracker module 100A is improved.

In addition, as illustrated in FIG. 4, a distance between the integrated circuit 81 and the capacitor C30 may be shorter than a distance between the integrated circuit 82 and the capacitor C30, and a distance between the integrated circuit 81 and the capacitor C20 may be shorter than a distance between the integrated circuit 82 and the capacitor C20. Here, in the plan view of the module laminate 90, the capacitor C30 is disposed to face the edge 801 (e.g., a first edge), and the capacitor C20 is disposed to face the edge 802 (e.g., a second edge).

According to the exemplary embodiment of FIG. 4, by disposing two smoothing capacitors on different edges while shortening two wires respectively connected to the two smoothing capacitors, heat generated from the two wires can be dissipated in a distributed manner. Thus, heat dissipation of the tracker module 100A is improved.

### 2.2 Disposition Configuration of Components of Tracker Module 100B According to Example 2

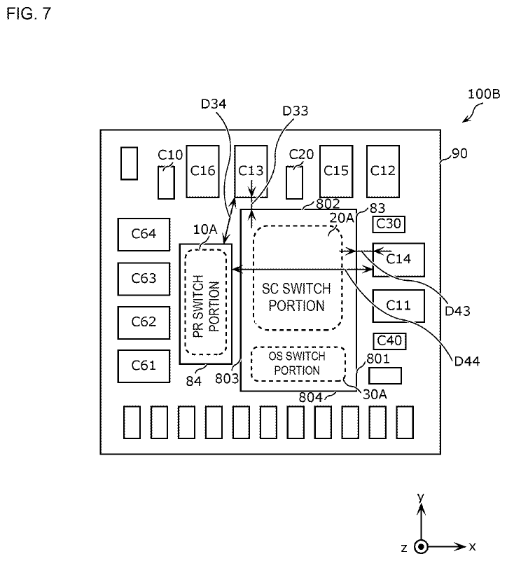

FIG. 7 is a plan view of a tracker module 100B according to Example 2. FIG. 7 illustrates a diagram of disposition of circuit components in a case where the main surface 90a out of the main surfaces 90a and 90b of the module laminate 90 facing each other is viewed from the side in the positive direction of the z-axis.

The tracker module 100B according to the present example illustrates a disposition configuration of a part of each circuit component forming the power supply circuit 1 according to the exemplary embodiment in FIG. 7.

As illustrated in FIG. 7, the tracker module 100B according to the present example includes the module laminate 90, integrated circuits 83 and 84, the capacitors C10, C20, C30, C40, C11, C12, C13, C14, C15, C16, C61, C62, C63, and C64, and the resin member 91 (not illustrated). The tracker module 100B according to the present example has different configurations of the two integrated circuits from the tracker module 100A according to Example 1. Hereinafter, in the tracker module 100B according to the present example, the same configurations as the tracker module 100A according to Example 1 will not be described, and only different configurations will be mainly described.

Each of the integrated circuits 83 and 84 is a semiconductor IC. For example, the integrated circuits 83 and 84 are configured using a CMOS and are manufactured through the SOI process. Each of the integrated circuits 83 and 84 may be formed of at least one of GaAs, SiGe, or GaN. Semiconductor materials of the integrated circuits 83 and 84 are not limited to the above materials.

The integrated circuit 83 includes the SC switch portion 20A and the OS switch portion 30A.

The SC switch portion 20A is configured with switches included in the switched-capacitor circuit 20. In an example, the SC switch portion 20A includes the switches S11, S12, S13, S14, S21, S22, S23, S24, S31, S32, S33, S34, S41, S42, S43, and S44.

The OS switch portion 30A is configured with switches included in the supply modulator 30. In an example, the OS switch portion 30A includes the switches S51, S52, S53, and S54.

The integrated circuit 84 includes the PR switch portion 10A. The PR switch portion 10A is configured with switches included in the pre-regulator circuit 10. In an example, the PR switch portion 10A includes the switches S61, S62, S63, S71, and S72.

The capacitors C10, C20, C30, C40, C11, C12, C13, C14, C15, and C16 are capacitors included in the switched-capacitor circuit 20. In addition, the capacitors C51 and C52 are capacitors included in the filter circuit 40. In addition, the capacitors C61, C62, C63, and C64 are capacitors included in the pre-regulator circuit 10.

The tracker module 100B may include at least one of the capacitors included in the switched-capacitor circuit 20 among the capacitors C10 to C64. In addition, the SC switch portion 20A may include at least one of the switches S11 to S44, the OS switch portion 30A may include at least one of the switches S51 to S54, and the PR switch portion 10A may include at least one of the switches S61 to S72.

In a case where the PR switch portion 10A, the SC switch portion 20A, and the OS switch portion 30A are accommodated in one integrated circuit, heat dissipation of the tracker module is decreased. In an example, in the tracker module 100B according to the present example, the PR switch portion 10A, the SC switch portion 20A, and the OS switch portion 30A are disposed to be distributed between the two integrated circuits 83 and 84. Accordingly, heat dissipation of the tracker module 100B is improved.

In addition, the integrated circuit 83 may include the SC switch portion 20A and the OS switch portion 30A, and the integrated circuit 84 different from the integrated circuit 83 may include the PR switch portion 10A.

In addition, while illustration is not provided in FIG. 7, the wires connecting each circuit component illustrated in FIG. 3 are formed inside the module laminate 90 and on the main surfaces 90a and 90b. In addition, the wires may be bonding wires of which both ends are joined to any of the main surfaces 90a and 90b and the circuit components or may be terminals, electrodes, or wires formed on the surfaces of the circuit components.

As illustrated in FIG. 7, in the tracker module 100B, a distance D43 between the integrated circuit 83 and the capacitor C14 is shorter than a distance D44 between the integrated circuit 84 and the capacitor C14.

The switched-capacitor circuit 20 and the pre-regulator circuit 10 are in an adjacent relationship from the viewpoint of the circuit connection illustrated in FIG. 3, and the capacitor C14 is disposed close to the PR switch portion 10A from the viewpoint of wire resistance reduction. In an example, by disposing the capacitor C14 further closer to the SC switch portion 20A than the PR switch portion 10A, wire resistance between the capacitor C14 and the SC switch portion 20A can be substantially reduced.

According to the exemplary embodiment of FIG. 7, since the wire connecting the capacitor C14 to the switch of the SC switch portion 20A can be shortened by making the distance D43 shorter than the distance D44, parasitic resistance and parasitic inductance of the wire in the switched-capacitor circuit 20 can be decreased. Thus, since the plurality of high-accuracy and stable second voltages can be supplied to the supply modulator 30 from the switched-capacitor circuit 20, deterioration of the output waveform of the power supply voltage V_{ET} (i.e., output characteristics of the power supply voltage) output from the tracker module 100B can be suppressed.

A capacitor of which a distance to the integrated circuit 83 is shorter than a distance to the integrated circuit 84 is not limited to the capacitor C14. A capacitor having such a relationship may be at least one of the capacitors C10 to C16 included in the switched-capacitor circuit 20. According to this configuration, since the wire connecting the capacitor of the switched-capacitor circuit 20 to the switch of the SC switch portion 20A can be shortened, parasitic resistance and parasitic inductance of the wire in the switched-capacitor circuit 20 can be decreased.

In addition, the integrated circuit 83 is adjacent to the capacitor C14. According to this configuration, since the wire connecting the capacitor C14 to the switch of the SC switch portion 20A can be shortened, parasitic resistance and parasitic inductance of the wire in the switched-capacitor circuit 20 can be decreased.

In addition, in the present example, the SC switch portion 20A of the integrated circuit 83 is adjacent to the capacitor C14. According to this configuration, since the wire connecting the capacitor C14 to the switch of the SC switch portion 20A can be further shortened, parasitic resistance and parasitic inductance of the wire in the switched-capacitor circuit 20 can be further decreased.

In addition, the capacitor C14 is one of the pair of flying capacitors. According to this configuration, since the wires connected to the flying capacitors can be shortened, the high-accuracy and stable second voltages having high voltage levels can be supplied to the supply modulator 30 from the switched-capacitor circuit 20, and deterioration of the output waveform of the power supply voltage V_{ET} (output characteristics of the power supply voltage) output from the tracker module 100B can be effectively suppressed.

Furthermore, the capacitor of which the distance to the integrated circuit 83 is shorter than the distance to the integrated circuit 84 is desirably the capacitor C11 or C14.

The capacitors C11 and C14 are capacitors to which the highest potential (voltage V4) is applied among the plurality of capacitors included in the switched-capacitor circuit 20. According to this configuration, the high-accuracy and stable second voltages having high voltage levels can be supplied to the supply modulator 30 from the switched-capacitor circuit 20, and deterioration of the output waveform of the power supply voltage V_{ET} output from the tracker module 100B can be effectively suppressed.

Furthermore, in the present example, as illustrated in FIG. 7, a distance D33 between the integrated circuit 83 and the capacitor C13 is shorter than a distance D34 between the integrated circuit 84 and the capacitor C13, in addition to that of the capacitor C14.

In the plan view of the module laminate 90, the integrated circuit 83 has a rectangular peripheral shape and has the four edges 801, 802, 803, and 804. Here, the capacitor C14 is disposed to face the edge 801 (e.g., a first edge), and the capacitor C13 is disposed to face the edge 802 (e.g., a second edge).

According to the exemplary embodiment of FIG. 7, by disposing the capacitors C13 and C14 on different edges while shortening the wire connected to the capacitor C14 and the wire connected to the capacitor C13, heat generated from the two wires can be dissipated in a distributed manner. Thus, heat dissipation of the tracker module 100B is improved. A combination of two capacitors disposed to be distributed on two different edges of the integrated circuit 83 is not limited to the capacitors C14 and C13 and may be a combination of any two capacitors of the plurality of capacitors included in the switched-capacitor circuit 20.

In addition, as illustrated in FIG. 7, the distance D43 between the integrated circuit 83 and the capacitor C14 may be shorter than the distance D44 between the integrated circuit 84 and the capacitor C14, and a distance between the integrated circuit 83 and the capacitor C15 may be shorter than a distance between the integrated circuit 84 and the capacitor C15. Here, in the plan view of the module laminate 90, the capacitor C14 is disposed to face the edge 801 (e.g., a first edge), and the capacitor C15 is disposed to face the edge 802 (e.g., a second edge).

According to the exemplary embodiment of FIG. 7, by disposing the pair of flying capacitors on different edges while shortening two wires respectively connected to the pair of flying capacitors, heat generated from the two wires can be dissipated in a distributed manner. Thus, heat dissipation of the tracker module 100B is improved.

In addition, a distance between the integrated circuit 83 and one of the pair of flying capacitors may be shorter than a distance between the integrated circuit 84 and the one, and a distance between the integrated circuit 83 and a smoothing capacitor may be shorter than a distance between the integrated circuit 84 and the smoothing capacitor. Here, in the plan view of the module laminate 90, the one of the pair of flying capacitors may be disposed to face the edge 801 (e.g., a first edge), and the smoothing capacitor may be disposed to face the edge 802 (e.g., a second edge).

According to the exemplary embodiment of FIG. 7, by disposing the flying capacitors and the smoothing capacitor on different edges while shortening the wire connected to one of the pair of flying capacitors and the wire connected to the smoothing capacitor, heat generated from the two wires can be dissipated in a distributed manner. Thus, heat dissipation of the tracker module 100B is improved.

In addition, as illustrated in FIG. 7, a distance between the integrated circuit 83 and the capacitor C30 may be shorter than a distance between the integrated circuit 84 and the capacitor C30, and a distance between the integrated circuit 83 and the capacitor C20 may be shorter than a distance between the integrated circuit 84 and the capacitor C20. Here, in the plan view of the module laminate 90, the capacitor C30 is disposed to face the edge 801 (e.g., a first edge), and the capacitor C20 is disposed to face the edge 802 (e.g., a second edge).

According to this configuration, by disposing two smoothing capacitors on different edges while shortening two wires respectively connected to the two smoothing capacitors, heat generated from the two wires can be dissipated in a distributed manner. Thus, heat dissipation of the tracker module 100B is improved.

### 2.3 Disposition Configuration of Components of Tracker Module 100C According to Example 3

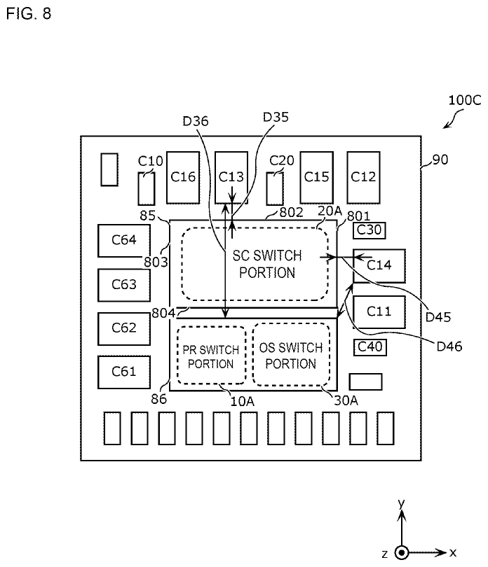

FIG. 8 is a plan view of a tracker module 100C according to Example 3. FIG. 8 illustrates a diagram of disposition of circuit components in a case where the main surface 90a out of the main surfaces 90a and 90b of the module laminate 90 facing each other is viewed from the side in the positive direction of the z-axis.

The tracker module 100C according to the present example illustrates a disposition configuration of a part of each circuit component forming the power supply circuit 1 according to the exemplary embodiment in FIG. 8.

As illustrated in FIG. 8, the tracker module 100C according to the present example includes the module laminate 90, integrated circuits 85 and 86, the capacitors C10, C20, C30, C40, C11, C12, C13, C14, C15, C16, C61, C62, C63, and C64, and the resin member 91 (not illustrated). The tracker module 100C according to the present example has different configurations of the two integrated circuits from the tracker module 100A according to Example 1. Hereinafter, in the tracker module 100C according to the present example, the same configurations as the tracker module 100A according to Example 1 will not be described, and only different configurations will be mainly described.

Each of the integrated circuits 85 and 86 is a semiconductor IC. For example, the integrated circuits 85 and 86 are configured using a CMOS and are manufactured through the SOI process. Each of the integrated circuits 85 and 86 may be formed of at least one of GaAs, SiGe, or GaN. Semiconductor materials of the integrated circuits 85 and 86 are not limited to the above materials.

The integrated circuit 85 includes the SC switch portion 20A.

The SC switch portion 20A is configured with switches included in the switched-capacitor circuit 20. In an example, the SC switch portion 20A includes the switches S11, S12, S13, S14, S21, S22, S23, S24, S31, S32, S33, S34, S41, S42, S43, and S44.

The integrated circuit 86 includes the PR switch portion 10A and the OS switch portion 30A.

The PR switch portion 10A is configured with switches included in the pre-regulator circuit 10. In an example, the PR switch portion 10A includes the switches S61, S62, S63, S71, and S72.

The OS switch portion 30A is configured with switches included in the supply modulator 30. In an example, the OS switch portion 30A includes the switches S51, S52, S53, and S54.

The capacitors C10, C20, C30, C40, C11, C12, C13, C14, C15, and C16 are capacitors included in the switched-capacitor circuit 20. In addition, the capacitors C51 and C52 are capacitors included in the filter circuit 40. In addition, the capacitors C61, C62, C63, and C64 are capacitors included in the pre-regulator circuit 10.

The tracker module 100C may include at least one of the capacitors included in the switched-capacitor circuit 20 among the capacitors C10 to C64. In addition, the SC switch portion 20A may include at least one of the switches S11 to S44, the OS switch portion 30A may include at least one of the switches S51 to S54, and the PR switch portion 10A may include at least one of the switches S61 to S72.

In a case where the PR switch portion 10A, the SC switch portion 20A, and the OS switch portion 30A are accommodated in one integrated circuit, heat dissipation of the tracker module is decreased. In an example, in the tracker module 100C according to the present example, the PR switch portion 10A, the SC switch portion 20A, and the OS switch portion 30A are disposed to be distributed between the two integrated circuits 85 and 86. Accordingly, heat dissipation of the tracker module 100C is improved.

In addition, the integrated circuit 85 may include the SC switch portion 20A, and the integrated circuit 86 different from the integrated circuit 85 may include the PR switch portion 10A and the OS switch portion 30A.

In addition, while illustration is not provided in FIG. 8, the wires connecting each circuit component illustrated in FIG. 3 are formed inside the module laminate 90 and on the main surfaces 90a and 90b. In addition, the wires may be bonding wires of which both ends are joined to any of the main surfaces 90a and 90b and the circuit components or may be terminals, electrodes, or wires formed on the surfaces of the circuit components.

As illustrated in FIG. 8, in the tracker module 100C, a distance D45 between the integrated circuit 85 and the capacitor C14 is shorter than a distance D46 between the integrated circuit 86 and the capacitor C14.

The switched-capacitor circuit 20, the pre-regulator circuit 10, and the supply modulator 30 are in an adjacent relationship from the viewpoint of the circuit connection illustrated in FIG. 3, and the capacitor C14 is disposed close to the PR switch portion 10A and the OS switch portion 30A from the viewpoint of wire resistance reduction. In an example, by disposing the capacitor C14 further closer to the SC switch portion 20A than the PR switch portion 10A and the OS switch portion 30A, wire resistance between the capacitor C14 and the SC switch portion 20A can be substantially reduced.

According to the exemplary embodiment of FIG. 8, since the wire connecting the capacitor C14 to the switch of the SC switch portion 20A can be shortened by making the distance D45 shorter than the distance D46, parasitic resistance and parasitic inductance of the wire in the switched-capacitor circuit 20 can be decreased. Thus, since the plurality of high-accuracy and stable second voltages can be supplied to the supply modulator 30 from the switched-capacitor circuit 20, deterioration of the output waveform of the power supply voltage V_{ET} (i.e., output characteristics of the power supply voltage) output from the tracker module 100C can be suppressed.

A capacitor of which a distance to the integrated circuit 85 is shorter than a distance to the integrated circuit 86 is not limited to the capacitor C14. A capacitor having such a relationship may be at least one of the capacitors C10 to C16 included in the switched-capacitor circuit 20. According to this configuration, since the wire connecting the capacitor of the switched-capacitor circuit 20 to the switch of the SC switch portion 20A can be shortened, parasitic resistance and parasitic inductance of the wire in the switched-capacitor circuit 20 can be decreased.

In addition, the integrated circuit 85 is adjacent to the capacitor C14. According to this configuration, since the wire connecting the capacitor C14 to the switch of the SC switch portion 20A can be shortened, parasitic resistance and parasitic inductance of the wire in the switched-capacitor circuit 20 can be decreased.

In addition, in the present example, the SC switch portion 20A of the integrated circuit 85 is adjacent to the capacitor C14. According to this configuration, since the wire connecting the capacitor C14 to the switch of the SC switch portion 20A can be further shortened, parasitic resistance and parasitic inductance of the wire in the switched-capacitor circuit 20 can be further decreased.

In addition, the capacitor C14 is one of the pair of flying capacitors. According to the capacitor C14 being the one of the pair of flying capacitors, since the wires connected to the flying capacitors can be shortened, the high-accuracy and stable second voltages having high voltage levels can be supplied to the supply modulator 30 from the switched-capacitor circuit 20, and deterioration of the output waveform of the power supply voltage V_{ET} output from the tracker module 100C can be effectively suppressed.

Furthermore, the capacitor of which the distance to the integrated circuit 85 is shorter than the distance to the integrated circuit 86 is desirably the capacitor C11 or C14.

The capacitors C11 and C14 are capacitors to which the highest potential (voltage V4) is applied among the plurality of capacitors included in the switched-capacitor circuit 20. According to this configuration, the high-accuracy and stable second voltages having high voltage levels can be supplied to the supply modulator 30 from the switched-capacitor circuit 20, and deterioration of the output waveform of the power supply voltage V_{ET} (output characteristic of the power supply voltage) output from the tracker module 100C can be effectively suppressed.

Furthermore, in the present example, as illustrated in FIG. 8, a distance D35 between the integrated circuit 85 and the capacitor C13 is shorter than a distance D36 between the integrated circuit 86 and the capacitor C13, in addition to that of the capacitor C14.

In the plan view of the module laminate 90, the integrated circuit 85 has a rectangular peripheral shape and has the four edges 801, 802, 803, and 804. Here, the capacitor C14 is disposed to face the edge 801 (e.g., a first edge), and the capacitor C13 is disposed to face the edge 802 (e.g., a second edge).

According to this configuration, by disposing the capacitors C13 and C14 on different edges while shortening the wire connected to the capacitor C14 and the wire connected to the capacitor C13, heat generated from the two wires can be dissipated in a distributed manner. Thus, heat dissipation of the tracker module 100C is improved. A combination of two capacitors disposed to be distributed on two different edges of the integrated circuit 85 is not limited to the capacitors C14 and C13 and may be a combination of any two capacitors of the plurality of capacitors included in the switched-capacitor circuit 20.

In addition, as illustrated in FIG. 8, the distance D45 between the integrated circuit 85 and the capacitor C14 may be shorter than the distance D46 between the integrated circuit 86 and the capacitor C14, and a distance between the integrated circuit 85 and the capacitor C15 may be shorter than a distance between the integrated circuit 86 and the capacitor C15. Here, in the plan view of the module laminate 90, the capacitor C14 is disposed to face the edge 801 (e.g., a first edge), and the capacitor C15 is disposed to face the edge 802 (e.g., a second edge).

According to this configuration, by disposing the pair of flying capacitors on different edges while shortening two wires respectively connected to the pair of flying capacitors, heat generated from the two wires can be dissipated in a distributed manner. Thus, heat dissipation of the tracker module 100C is improved.

In addition, a distance between the integrated circuit 85 and one of the pair of flying capacitors may be shorter than a distance between the integrated circuit 86 and the one, and a distance between the integrated circuit 85 and a smoothing capacitor may be shorter than a distance between the integrated circuit 86 and the smoothing capacitor. Here, in the plan view of the module laminate 90, the one of the pair of flying capacitors may be disposed to face the edge 801 (e.g., a first edge), and the smoothing capacitor may be disposed to face the edge 802 (e.g., a second edge).

According to this configuration, by disposing the flying capacitors and the smoothing capacitor on different edges while shortening the wire connected to one of the pair of flying capacitors and the wire connected to the smoothing capacitor, heat generated from the two wires can be dissipated in a distributed manner. Thus, heat dissipation of the tracker module 100C is improved.

In addition, as illustrated in FIG. 8, a distance between the integrated circuit 85 and the capacitor C30 may be shorter than a distance between the integrated circuit 86 and the capacitor C30, and a distance between the integrated circuit 85 and the capacitor C20 may be shorter than a distance between the integrated circuit 86 and the capacitor C20. Here, in the plan view of the module laminate 90, the capacitor C30 is disposed to face the edge 801 (e.g., a first edge), and the capacitor C20 is disposed to face the edge 802 (e.g., a second edge).

According to this configuration, by disposing two smoothing capacitors on different edges while shortening two wires respectively connected to the two smoothing capacitors, heat generated from the two wires can be dissipated in a distributed manner. Thus, heat dissipation of the tracker module 100C is improved.

### 3 Effects

As described above, the tracker modules 100A and 100C according to the examples include the module laminate 90, a first integrated circuit and a second integrated circuit that are disposed on the module laminate 90, and a capacitor that is disposed on the module laminate 90 and that is included in the switched-capacitor circuit 20 configured to generate the plurality of discrete voltages based on the input voltage. The first integrated circuit includes a switch included in the switched-capacitor circuit 20. The second integrated circuit includes a switch included in the supply modulator 30 configured to selectively output at least one of the plurality of discrete voltages based on the envelope signal. A distance between the first integrated circuit and the capacitor is shorter than a distance between the second integrated circuit and the capacitor.

In the switched-capacitor circuit 20, by applying the digital ET, charging and discharging of the capacitor are repeated at a high speed, and the plurality of discrete voltages having rapid changes need to be stably supplied to the supply modulator 30 with high accuracy. Thus, it is desirable that charges can move through a wire connecting the capacitor to the switch connected to the capacitor at a high speed with low resistance.

According to the above configuration, since the distance between the first integrated circuit and the capacitor is shorter than the distance between the second integrated circuit and the capacitor, the wire connecting the capacitor to the switch of the SC switch portion 20A can be shortened. Thus, parasitic resistance and parasitic inductance of the wire in the switched-capacitor circuit 20 can be decreased. Thus, since the plurality of high-accuracy and stable discrete voltages can be supplied to the supply modulator 30 from the switched-capacitor circuit 20, deterioration of the output waveform of the power supply voltage V_{ET} (output characteristics of the power supply voltage) output from the tracker module can be suppressed.

In addition, the tracker modules 100B and 100C according to the examples include the module laminate 90, the first integrated circuit and the second integrated circuit disposed on the module laminate 90, and a capacitor that is disposed on the module laminate 90 and that is included in the switched-capacitor circuit 20 configured to generate the plurality of discrete voltages based on the input voltage. The first integrated circuit includes a switch included in the switched-capacitor circuit 20. The second integrated circuit includes a switch included in the pre-regulator circuit 10 configured to convert the input voltage into the first voltage and output the first voltage to the switched-capacitor circuit 20. The distance between the first integrated circuit and the capacitor is shorter than the distance between the second integrated circuit and the capacitor.

According to the above configurations of the tracker modules 100A, 100B and 100C, since the distance between the first integrated circuit and the capacitor is shorter than the distance between the second integrated circuit and the capacitor, the wire connecting the capacitor to the switch of the SC switch portion 20A can be shortened. Thus, parasitic resistance and parasitic inductance of the wire in the switched-capacitor circuit 20 can be decreased. Thus, since the plurality of high-accuracy and stable second voltages can be supplied to the supply modulator 30 from the switched-capacitor circuit 20, deterioration of the output waveform of the power supply voltage V_{ET} (output characteristics of the power supply voltage) output from the tracker module can be suppressed.

In addition, for example, in the tracker modules 100A, 100B, and 100C, the capacitor may be one of the pair of flying capacitors that are charged and discharged in a complementary manner among the plurality of capacitors included in the switched-capacitor circuit 20.

According to the exemplary embodiments of the tracker modules 100A, 100B, and 100C, since the wires connected to the flying capacitors can be shortened, the high-accuracy and stable second voltages having high voltage levels can be supplied to the supply modulator 30 from the switched-capacitor circuit 20, and deterioration of the output waveform of the power supply voltage V_{ET} output from the tracker module can be effectively suppressed.

In addition, for example, in the tracker modules 100A, 100B, and 100C, the capacitor may be a capacitor to which the highest potential is applied among the plurality of capacitors included in the switched-capacitor circuit 20.

According to this configuration, parasitic resistance and parasitic inductance of the wire having the largest amount of charge movement can be decreased. Thus, deterioration of the output waveform of the power supply voltage V_{ET} output from the tracker module can be effectively suppressed.

In addition, for example, in the tracker modules 100A, 100B, and 100C, the switched-capacitor circuit 20 may include a plurality of capacitors. In the plan view of the module laminate 90, the first integrated circuit may have a rectangular peripheral shape. One of the plurality of capacitors may be disposed to face the edge 801 forming a periphery of the first integrated circuit. Other one of the plurality of capacitors may be disposed to face the edge 802 different from the edge 801 forming the periphery of the first integrated circuit. A distance between the first integrated circuit and the one of the plurality of capacitors may be shorter than a distance between the second integrated circuit and the one of the plurality of capacitors. A distance between the first integrated circuit and the other one of the plurality of capacitors may be shorter than a distance between the second integrated circuit and the other one of the plurality of capacitors.

According to this configuration, by disposing the two capacitors on different edges while shortening a wire connected to the one of the plurality of capacitors and a wire connected to the other one of the plurality of capacitors, heat generated from the two wires can be dissipated in a distributed manner. Thus, heat dissipation of the tracker module is improved.

In addition, for example, in the tracker modules 100A, 100B, and 100C, the switched-capacitor circuit 20 may include a pair of flying capacitors that are charged and discharged in a complementary manner, and a smoothing capacitor that smooths voltages of the pair of capacitors. The one of the plurality of capacitors may be one of the pair of flying capacitors. The other one of the plurality of capacitors may be the other of the pair of flying capacitors.

According to this configuration, by disposing the pair of flying capacitors on different edges while shortening two wires respectively connected to the pair of flying capacitors, heat generated from the two wires can be dissipated in a distributed manner. Thus, heat dissipation of the tracker module is improved.

In addition, for example, in the tracker modules 100A, 100B, and 100C, the one of the plurality of capacitors may be one of the pair of flying capacitors, and the other one of the plurality of capacitors may be the smoothing capacitor.

According to this configuration, by disposing the flying capacitors and the smoothing capacitor on different edges while shortening the wire connected to one of the pair of flying capacitors and the wire connected to the smoothing capacitor, heat generated from the two wires can be dissipated in a distributed manner. Thus, heat dissipation of the tracker module is improved.

In addition, for example, in the tracker modules 100A, 100B, and 100C, the switched-capacitor circuit 20 may include a pair of flying capacitors that are charged and discharged in a complementary manner, and a plurality of smoothing capacitors. The one of the plurality of capacitors may be one of the plurality of smoothing capacitors. The other one of the plurality of capacitors may be other one of the plurality of smoothing capacitors.

According to this configuration, by disposing two smoothing capacitors on different edges while shortening two wires respectively connected to the two smoothing capacitors, heat generated from the two wires can be dissipated in a distributed manner. Thus, heat dissipation of the tracker module is improved.

In addition, the tracker modules 100A and 100C according to the examples include the module laminate 90, the first circuit, and the second circuit. The first circuit includes the capacitor C12 including the first electrode and the second electrode, the capacitor C15 including the third electrode and the fourth electrode, and the switches S21, S32, S22, S31, S23, S34, S24, and S33. One end of the switch S21 and one end of the switch S22 are connected to the first electrode. One end of the switch S32 and one end of the switch S31 are connected to the second electrode. One end of the switch S23 and one end of the switch S24 are connected to the third electrode. One end of the switch S34 and one end of the switch S33 are connected to the fourth electrode. The other end of the switch S21, the other end of the switch S32, the other end of the switch S23, and the other end of the switch S34 are connected to each other. The other end of the switch S22 is connected to the other end of the switch S24. The other end of the switch S31 is connected to the other end of the switch S33. The second circuit includes the output terminal 130, the switch S53 connected between the output terminal 130 and the other end of the switch S21, the other end of the switch S32, the other end of the switch S23, and the other end of the switch S34, and the switch S52 connected between the output terminal 130 and the other end of the switch S22 and the other end of the switch S24. The switches S21, S22, S23, S24, S31, S32, S33, and S34 are included in the first integrated circuit. The switches S52 and S53 are included in the second integrated circuit. The capacitor C12, the capacitor C15, the first integrated circuit, and the second integrated circuit are disposed on the module laminate 90. A distance between the first integrated circuit and one of the capacitors C12 and C15 is shorter than a distance between the second integrated circuit and the one of the capacitors C12 and C15.

According to the above configuration, since the distance between the first integrated circuit and the one of the capacitors C12 and C15 is shorter than the distance between the second integrated circuit and the one, the wire connecting the one to the switch of the first circuit can be shortened. Thus, parasitic resistance and parasitic inductance of the wire in the first circuit can be decreased. Thus, since the plurality of high-accuracy and stable second voltages can be supplied to the second circuit from the first circuit, deterioration of the output waveform of the power supply voltage V_{ET} output from the tracker module can be suppressed.

In addition, for example, in the tracker modules 100A and 100C, the capacitors C12 and C15 may be capacitors to which the highest potential is applied among the plurality of capacitors included in the first circuit.

According to this configuration, parasitic resistance and parasitic inductance of the wire having the largest amount of charge movement can be decreased. Thus, deterioration of the output waveform of the power supply voltage V_{ET} output from the tracker module can be effectively suppressed.

In addition, for example, in the tracker modules 100A and 100C, the first circuit may further include the third capacitor. In the plan view of the module laminate 90, the first integrated circuit may have a rectangular peripheral shape. Moreover, the one of the capacitors C12 and C15 may be disposed to face the edge 802 forming the periphery of the first integrated circuit. The third capacitor may be disposed to face the edge 801 that forms the periphery of the first integrated circuit and that is different from the edge 802. A distance between the first integrated circuit and the third capacitor may be shorter than a distance between the second integrated circuit and the third capacitor.

According to this configuration, by disposing the one of the capacitors C12 and C15 and the third capacitor on different edges while shortening the wire connected to the one and the wire connected to the third capacitor, heat generated from the two wires can be dissipated in a distributed manner. Thus, heat dissipation of the tracker module is improved.

In addition, for example, in the tracker modules 100A and 100C, the third capacitor (e.g., capacitor C30) may include the fifth electrode and the sixth electrode. The fifth electrode may be connected to the other end of the switch S21, the other end of the switch S32, the other end of the switch S23, and the other end of the switch S34. The sixth electrode may be connected to the other end of the switch S22 and the other end of the switch S24.

According to this configuration, by disposing the flying capacitor (e.g., capacitor C15) and the smoothing capacitor (e.g., capacitor C30) on different edges while shortening the wire connected to the flying capacitor and the wire connected to the smoothing capacitor, heat generated from the two wires can be dissipated in a distributed manner. Thus, heat dissipation of the tracker module is improved.

In addition, for example, in the tracker modules 100A and 100C, the first circuit may further include the fourth capacitor (e.g., capacitor C20) including a seventh electrode and an eighth electrode. The seventh electrode may be connected to the other end of the switch S21, the other end of the switch S32, the other end of the switch S23, and the other end of the switch S34. The eighth electrode may be connected to the other end of the switch S31 and the other end of the switch S33. The third capacitor (e.g., capacitor C30) may be disposed to face the edge 801 forming the periphery of the first integrated circuit. The fourth capacitor (e.g., capacitor C20) may be disposed to face the edge 802 that forms the periphery of the first integrated circuit and that is different from the edge 801. The distance between the first integrated circuit and the third capacitor may be shorter than the distance between the second integrated circuit and the third capacitor. A distance between the first integrated circuit and the fourth capacitor may be shorter than a distance between the second integrated circuit and the fourth capacitor.

According to this configuration, by disposing two smoothing capacitors (e.g., capacitors C30 and C20) on different edges while shortening two wires respectively connected to the two smoothing capacitors, heat generated from the two wires can be dissipated in a distributed manner. Thus, heat dissipation of the tracker module is improved.

In addition, for example, in the tracker modules 100A and 100C, a distance between the first integrated circuit and the first capacitor (e.g., capacitor C12) may be shorter than a distance between the second integrated circuit and the first capacitor, and a distance between the first integrated circuit and the second capacitor (e.g., capacitor C15) may be shorter than a distance between the second integrated circuit and the second capacitor.

According to this configuration, since the wires connecting the pair of flying capacitors to the switch of the first circuit can be shortened, parasitic resistance and parasitic inductance of the wires in the first circuit can be decreased. Thus, since the plurality of high-accuracy and stable second voltages can be supplied to the second circuit from the first circuit, deterioration of the output waveform of the power supply voltage V_{ET} output from the tracker module can be suppressed.

In addition, the communication device 7 according to the present disclosure includes the RFIC 5 that processes a radio frequency signal, the power amplifier circuit 2 that transmits the radio frequency signal between the RFIC 5 and the antenna 6, and any of the tracker modules 100A, 100B, and 100C that supply the power supply voltage V_{ET} to the power amplifier circuit 2.

According to this configuration, the communication device 7 can achieve the same effect as the effects of the tracker modules 100A, 100B, and 100C.

It is noted that while the tracker module and the communication device according to the present disclosure have been described above based on the embodiments and on the examples in FIGS. 1-8, the tracker module and the communication device according to the present disclosure are not limited to the embodiments and the examples in FIGS. 1-8. Thus, it should be appreciated that the present invention also includes other embodiments implemented by combining any constituents in the embodiments and in the examples in FIGS. 1-8, modification examples obtained by carrying out various modifications perceived by those skilled in the art to the embodiments and the examples without departing from the gist of the present disclosure, and various devices incorporating the tracker module and the communication device.

For example, in the circuit configurations of the tracker module and the communication device according to the exemplary embodiments in FIGS. 1-8, other circuit elements, wires, and the like may be provided on the paths connecting each circuit element and the signal paths disclosed in the drawings.

The present disclosure can be widely used for communication devices such as a mobile phone as a radio frequency module or a communication device disposed in a front end unit supporting multiple bands.

### REFERENCE SIGNS LIST

1 Power supply circuit
2 Power amplifier circuit
3 Filter
4 PA control circuit
5 RFIC
6 Antenna
7 Communication device
10 Pre-regulator circuit
10A PR switch portion
20 Switched-capacitor circuit
20A SC switch portion
30 Supply modulator
30A OS switch portion
40 Filter circuit
50 Direct current power source
81, 82, 83, 84, 85, 86 Integrated circuit
90 Module laminate
90a, 90b Main surface
91 Resin member
100A, 100B, 100C Tracker module
110, 131, 132, 133, 134, 140 Input terminal
111, 112, 113, 114, 130, 141 Output terminal
115, 116 Inductor connection terminal
117, 120, 135 Control terminal
150 External connection electrode
181, 182 Input-output electrode
801, 802, 803, 804 Edge
821 Input electrode
C10, C11, C12, C13, C14, C15, C16, C20, C30, C40, C51, C52, C61, C62, C63, C64 Capacitor
L51, L52, L53 Inductor
L71 Power inductor
R51 Resistor
S11, S12, S13, S14, S21, S22, S23, S24, S31, S32, S33, S34, S41, S42, S43, S44, S51, S52, S53, S54, S61, S62, S63, S71, S72 Switch

What is claimed is:

1. A tracker module comprising:
a module laminate;
a first integrated circuit and a second integrated circuit that are disposed on the module laminate; and
a capacitor that is disposed on the module laminate and included in a plurality of capacitors of a switched-capacitor circuit that is configured to generate a plurality of discrete voltages based on an input voltage,
wherein the first integrated circuit includes a switch that is included in the switched-capacitor circuit,
wherein the second integrated circuit includes a switch that is included in at least one of a supply modulator and a pre-regulator circuit, the supply modulator being configured to selectively output at least one of the plurality of discrete voltages based on an envelope signal, the pre-regulator circuit being configured to convert the input voltage into a first voltage and output the first voltage to the switched-capacitor circuit, and
wherein a distance between the first integrated circuit and the capacitor is shorter than a distance between the second integrated circuit and the capacitor.

2. The tracker module according to claim 1, wherein the capacitor is one of a pair of flying capacitors that are configured to be charged and discharged in a complementary manner among the plurality of capacitors included in the switched-capacitor circuit.

3. The tracker module according to claim 1, wherein the capacitor is a capacitor to which a highest potential is applied among potentials applied to a plurality of capacitors included in the switched-capacitor circuit.

4. The tracker module according to claim 1, wherein:
in a plan view of the module laminate, a periphery of the first integrated circuit has a rectangular shape,
one of the plurality of capacitors is disposed adjacent to a first edge of the periphery of the first integrated circuit,
another one of the plurality of capacitors is disposed adjacent to a second edge of the periphery of the first integrated circuit, and
a distance between the first integrated circuit and the one of the plurality of capacitors is shorter than a distance between the second integrated circuit and the one of the plurality of capacitors, and a distance between the first integrated circuit and the other one of the plurality of capacitors is shorter than a distance between the second integrated circuit and the other one of the plurality of capacitors.

5. The tracker module according to claim 4, wherein the plurality of the capacitors of the switched-capacitor circuit includes:
a pair of flying capacitors that are configured to be charged and discharged in a complementary manner by repeating a first phase and a second phase, and
a smoothing capacitor configured to smooth voltages of the pair of flying capacitors to reduce fluctuations of the voltages, the one of the plurality of capacitors being a first one of the pair of flying capacitors, and the other one of the plurality of capacitors being a second one of the pair of flying capacitors.

6. The tracker module according to claim 4, wherein the plurality of the capacitors of the switched-capacitor circuit includes:
a pair of flying capacitors that are configured to be charged and discharged in a complementary manner by repeating a first phase and a second phase, and
a smoothing capacitor configured to smooth voltages of the pair of flying capacitors to reduce fluctuations of the voltages, the one of the plurality of capacitors being one of the pair of flying capacitors, and the other one of the plurality of capacitors being the smoothing capacitor.

7. The tracker module according to claim 4, wherein the plurality of the capacitors of the switched-capacitor circuit includes:
a pair of flying capacitors that are configured to be charged and discharged in a complementary manner by repeating a first phase and a second phase, and
a plurality of smoothing capacitors configured to smooth voltages of the plurality of capacitors to reduce fluctuations of the voltages, the one of the plurality of capacitors being a first one of the plurality of smoothing capacitors, and the other one of the plurality of capacitors being a second one of the plurality of smoothing capacitors.

8. A tracker module comprising:
a module laminate; and
a first circuit and a second circuit, wherein:
the first circuit includes:
a first capacitor including a first electrode and a second electrode,
a second capacitor including a third electrode and a fourth electrode, and
a first switch, a second switch, a third switch, a fourth switch, a fifth switch, a sixth switch, a seventh switch, and an eighth switch,
a first end of the first switch and a first end of the third switch are coupled to the first electrode,
a first end of the second switch and a first end of the fourth switch are coupled to the second electrode,
a first end of the fifth switch and a first end of the seventh switch are coupled to the third electrode,
a first end of the sixth switch and a first end of the eighth switch are coupled to the fourth electrode,
a second end of the first switch, a second end of the second switch, a second end of the fifth switch, and a second end of the sixth switch are coupled to each other,
a second end of the third switch is coupled to a second end of the seventh switch, and
a second end of the fourth switch is coupled to a second end of the eighth switch, and
the second circuit includes:
a first output terminal,
a ninth switch coupled to (i) the first output terminal and (ii) the second end of the first switch, the second end of the second switch, the second end of the fifth switch, and the second end of the sixth switch, and
a tenth switch coupled to (i) the first output terminal and (ii) the second end of the third switch and the second end of the seventh switch,
the first switch, the second switch, the third switch, the fourth switch, the fifth switch, the sixth switch, the seventh switch, and the eighth switch are included in a first integrated circuit,
the ninth switch and the tenth switch are included in a second integrated circuit,
the first capacitor, the second capacitor, the first integrated circuit, and the second integrated circuit are disposed on the module laminate, and
a distance between the first integrated circuit and the first capacitor is shorter than a distance between the second integrated circuit and the first capacitor.

9. The tracker module according to claim 8, wherein the first capacitor is a capacitor to which a highest potential is applied among potentials applied to a plurality of capacitors that is included in the first circuit.

10. The tracker module according to claim 8, wherein:
the first circuit further includes a third capacitor,
in a plan view of the module laminate, a periphery of the first integrated circuit has a rectangular shape,
the first capacitor is disposed adjacent to a first edge of the periphery of the first integrated circuit,
the third capacitor is disposed adjacent to a second edge of the periphery of the first integrated circuit, and
a distance between the first integrated circuit and the third capacitor is shorter than a distance between the second integrated circuit and the third capacitor.

11. The tracker module according to claim 10, wherein:
the third capacitor includes a fifth electrode and a sixth electrode,
the fifth electrode is coupled to the second end of the first switch, the second end of the second switch, the second end of the fifth switch, and the second end of the sixth switch, and
the sixth electrode is coupled to (i) the second end of the third switch and the second end of the seventh switch or (ii) the second end of the fourth switch and the second end of the eighth switch.

12. The tracker module according to claim 11, wherein:
the first circuit further includes a fourth capacitor including a seventh electrode and an eighth electrode,
the seventh electrode is coupled to the second end of the first switch, the second end of the second switch, the second end of the fifth switch, and the second end of the sixth switch,
the eighth electrode is coupled to the second end of the fourth switch and the second end of the eighth switch,
the fourth capacitor is disposed adjacent to a third edge of the periphery of the first integrated circuit, and
a distance between the first integrated circuit and the fourth capacitor is shorter than a distance between the second integrated circuit and the fourth capacitor.

13. The tracker module according to claim 8, wherein a distance between the first integrated circuit and the second capacitor is shorter than a distance between the second integrated circuit and the second capacitor.

14. A communication device, comprising:
a signal processing circuit configured to process a radio frequency signal;
a power amplifier circuit configured to transmit the radio frequency signal between the signal processing circuit and an antenna; and
a tracker module configured to supply a power supply voltage to the power amplifier circuit, wherein the tracker module comprises:
a module laminate;
a first integrated circuit and a second integrated circuit that are disposed on the module laminate; and
a capacitor that is disposed on the module laminate and included in a plurality of capacitors of a switched-capacitor circuit that are configured to generate a plurality of discrete voltages based on an input voltage,
wherein the first integrated circuit includes a switch that is included in the switched-capacitor circuit,
wherein the second integrated circuit includes a switch that is included in at least one of a supply modulator and a pre-regulator circuit, the supply modulator configured to selectively output at least one of the plurality of discrete voltages based on an envelope signal, the pre-regulator circuit configured to convert the input voltage into a first voltage and output the first voltage to the switched-capacitor circuit, and
wherein a distance between the first integrated circuit and the capacitor is shorter than a distance between the second integrated circuit and the capacitor.

15. The communication device according to claim 14, wherein the capacitor is one of a pair of flying capacitors that are configured to be charged and discharged in a complementary manner among the plurality of capacitors included in the switched-capacitor circuit.

16. The communication device according to claim 14, wherein the capacitor is a capacitor to which a highest potential is applied among potentials applied to a plurality of capacitors that is included in the switched-capacitor circuit.

17. The communication device according to claim 14, wherein:
in a plan view of the module laminate, the first integrated circuit has a rectangular peripheral shape,
one of the plurality of capacitors is disposed adjacent to a first edge of a periphery of the first integrated circuit,
another one of the plurality of capacitors is disposed adjacent to a second edge of the periphery of the first integrated circuit, and
a distance between the first integrated circuit and the one of the plurality of capacitors is shorter than a distance between the second integrated circuit and the one of the plurality of capacitors, and a distance between the first integrated circuit and the other one of the plurality of capacitors is shorter than a distance between the second integrated circuit and the other one of the plurality of capacitors.

18. The communication device according to claim 17, wherein the plurality of the capacitors of the switched-capacitor circuit includes:
a pair of flying capacitors that are configured to be charged and discharged in a complementary manner, and
a smoothing capacitor configured to smooth voltages of the pair of flying capacitors to reduce fluctuations of the voltages, the one of the plurality of capacitors being a first one of the pair of flying capacitors, and the other one of the plurality of capacitors being a second one of the pair of flying capacitors.

19. The communication device according to claim 17, wherein the plurality of the capacitors of the switched-capacitor circuit includes:
a pair of flying capacitors that are configured to be charged and discharged in a complementary manner, and
a smoothing capacitor configured to smooth voltages of the pair of flying capacitors to reduce fluctuations of the voltages, the one of the plurality of capacitors being one of the pair of flying capacitors, and the other one of the plurality of capacitors being the smoothing capacitor.

20. The communication device according to claim 17, wherein the plurality of the capacitors of the switched-capacitor circuit includes:
a pair of flying capacitors that are configured to be charged and discharged in a complementary manner, and
a plurality of smoothing capacitors configured to smooth voltages of the plurality of capacitors to reduce fluctuations of the voltages, the one of the plurality of capacitors is a first one of the plurality of smoothing capacitors, and the other one of the plurality of capacitors is a second one of the plurality of smoothing capacitors.
